(19) United States
(12) Patent Application Publication
(10) Pub. No.: US 2012/0212241 A1
(43) Pub. Date: Aug. 23, 2012

(54) INTERACTIVE PLAY SET WITH CAPACITIVE SENSORS

(75) Inventors: Michael Wallace, Vancouver, WA (US); Philip T. Odom, Portland, OR (US)

(73) Assignee: PURE IMAGINATION LLC, Vancouver, WA (US)

(21) Appl. No.: 13/403,909

(22) Filed: Feb. 23, 2012

Related U.S. Application Data
(60) Provisional application No. 61/445,956, filed on Feb. 23, 2011.

(51) Int. Cl. G01R 27/26

(52) U.S. Cl. 324/686

(57) ABSTRACT

Embodiments of an interactive play set with capacitive sensors, the play set configured to detect human touch, the presence or identity of small play objects, and play sound effects in response thereof. In some embodiments, play sets have capacitive sensors that detect the presence of play objects with coplanar sensor pads and ground pads in various geometries. In some embodiments, play sets have capacitive sensors that identify particular play objects by detecting the presence or absence of conductive tabs at a plurality of tab locations on each of the play objects.

### CROSS-REFERENCE TO RELATED APPLICATION

This application claims priority to co-pending provisional application Ser. No. 61/445/956, filed 23 Feb. 2011, which is hereby incorporated herein by reference.

### FIELD OF THE INVENTION

The present invention relates to board games or play sets. More particularly, the present invention relates to play sets that detect and react to objects placed on a game board.

### BACKGROUND

The recent proliferation of inexpensive computer processors and logic devices has influenced games, toys, books, and the like. Some game use embedded sensors in conjunction with control logic coupled to audio and/or visual input/output logic to enrich the interactive experience.

Many conventional stand-alone computer games provide a visual display of game activity through an electronic display system such as a pixilated flat panel display. Such displays lack the three-dimensional character and physical interaction inherent in typical board-based games. For example, a conventional board game may use of one or more movable playing pieces integral to the action of the game. Conversely, conventional board games often lack the audio and/or visual interaction and computerized game play offered by computer games.

A number of prior art patents have described games (e.g., board games), toys, books, and cards that utilize computers and sensors to detect human interaction with elements of the board games. The following represents a list of known related art:

| | | Date of |
|---|---|---|
| Reference: | Issued to: | Issue/Publication: |
| U.S. Pat. No. 6,955,603 | Jeffway, Jr. et al | Oct. 18, 2005 |
| U.S. Pat. No. 6,168,158 | Bulsink | Jan. 2, 2001 |
| U.S. Pat. No. 5,853,327 | Gilboa | Dec. 29, 1998 |
| U.S. Pat. No. 5,413,518 | Lin | May 9, 1995 |
| U.S. Pat. No. 5,188,368 | Ryan | Feb. 23, 1993 |
| U.S. Pat. No. 5,129,654 | Bogner | Jul. 14, 1992 |

The teachings of each of the above-listed citations (which does not itself incorporate essential material by reference) are herein incorporated by reference. None of the above inventions and patents, taken either singularly or in combination, is seen to describe an embodiment or embodiments of the instant invention described below and claimed herein.

For example, U.S. Pat. No. 5,853,327 “Computerized Game Board” describes a system that automatically senses the position of toy figures relative to a game board and thereby supplies input to a computerized game system. The system requires that each game piece to be sensed incorporate a transponder, which receives an excitatory electromagnetic signal from a signal generator and produces a response signal that is detected by one or more sensors embedded in the game board. The complexity and cost of such a system make it impractical for low-cost games and toys.

U.S. Pat. No. 5,129,654 “Electronic Game Apparatus,” U.S. Pat. No. 5,188,368 “Electronic Game Apparatus,” and U.S. Pat. No. 6,168,158 “Device for Detecting Playing Pieces on a Board” all describe systems using resonance frequency sensing to determine the position and/or identity of a game piece. Each system requires a resonator circuit coupled with some particular feature of each unique game piece, which increases the complexity and cost of the system while reducing the flexibility of use.

U.S. Pat. No. 5,413,518 “Proximity Responsive Toy” describes another example of a toy incorporating automatic sensing that utilizes a capacitive sensor coupled to a high frequency oscillator, whereby the frequency of the oscillator is determined in part by the proximity of any conductive object (such as a human hand) to the capacitive sensor. This system has the disadvantages of requiring specialized electronic circuitry that may limit the number of sensors that can be simultaneously deployed.

U.S. Pat. No. 6,955,603 “Interactive Gaming Device Capable of Perceiving User Movement” describes another approach to sensing player interaction by using a series of light emitters and light detectors to measure the intensity of light reflected from a player's hand or other body part. Such a system requires numerous expensive light emitters and light detectors, in particular for increasing the spatial sensitivity for detection.

Each of the prior art patents included above describes a game and/or toy that requires expensive components or manufacturing techniques and/or exhibits limited functionality. As will be described below, embodiments of the invention overcome these limitations

### SUMMARY AND ADVANTAGES

Embodiments of an interactive play set with capacitive sensors, the play set configured to detect human touch, the presence or identity of small play objects, and play sound effects in response thereof. In some embodiments, play sets have capacitive sensors that detect the presence of play objects with coplanar sensor pads and ground pads in various geometries. In some embodiments, play sets have capacitive sensors that identify particular play objects by detecting the presence or absence of conductive tabs at a plurality of tab locations on each of the play objects. Play objects may include toy vehicles, toy aircraft, figurines, toy buildings, etc.

The embodiments of the interactive play set present numerous advantages, including: (1) inexpensive and simple construction; (2) substantially one-sided triggering of the capacitive sensors; (3) thin construction; (4) substantially unique identification of multiple objects to trigger multiple events; (5) integration of printed art on a layer or substrate with the capacitive sensors; (6) integration of one or more detection sensors, one or more identification sensors, and/or one or more touch sensors.

Additional advantages of the invention will be set forth in part in the description which follows, and in part will be obvious from the description, or may be learned by practice of the invention. The advantages of the invention may be realized and attained by means of the instrumentalities and combinations particularly pointed out in the appended claims. Further benefits and advantages of the embodiments of the invention will become apparent from consideration of the following detailed description given with reference to the accompanying drawings, which specify and show preferred embodiments of the present invention.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

FIG. 1 illustrates a cross section of a sensor system with a capacitive sensor and a conductive object placed over the capacitive sensor.

FIGS. 2A and 2B illustrate binary tab patterns.

FIGS. 3A and 3B illustrate sensor arrays for binary sensing.

FIG. 4 illustrates a circular sensor array for binary sensing.

FIG. 5 illustrates an arcuate sensor array.

FIGS. 6A and 6B illustrate a sensor system with a switching sensor array and a connected tab array.

FIGS. 7A-C illustrate a play object with a floating skid.

FIGS. 8A-C illustrate a play object with a fixed skid.

FIG. 9 illustrates a play object with a skid positioned over a detection sensor.

FIGS. 10A and 10B illustrates sensor pad configurations for detection sensors.

FIGS. 11A and 11B illustrate a system for identifying play objects with skids of different lengths.

FIGS. 12A-12C illustrate one way to mount multiple connected tabs on the skid of a play object.

FIG. 13 illustrates an alignment system for a play object to enable correct identification.

FIG. 14 illustrates multiple connected tabs of an alternate embodiment to identify a toy vehicle.

FIG. 15 illustrates an embodiment of play set construction.

FIG. 16 illustrates play set construction of an alternate embodiment.

FIG. 17 illustrates play set construction of an embodiment including various elements.

FIG. 18 illustrates a play set design layout.

FIG. 19 illustrates the capacitive sensor layout for the set.

FIG. 20 illustrates a capacitive sensor for a parking space.

FIG. 21 illustrates vehicle identification sensor in a parking area.

FIG. 22 illustrates a drag racing/drift racing play set.

FIG. 23 illustrates finish sensor arrays at the finish line of a race.

FIG. 24 illustrates an airport play set including multiple runway sensors.

FIG. 25 illustrates a street block play set.

FIG. 26 illustrates a street corner capacitive sensor of an embodiment.

FIG. 27 illustrates a drift racing play set.

FIG. 28 illustrates drift circle capacitive sensors.

FIG. 29 illustrates a capacitive sensor to detect toy vehicle skidding motion.

FIG. 30 illustrates a road barrier in a play set.

FIG. 31 illustrates a traffic light in a play set.

FIG. 32 illustrates a street block play set including intersection capacitive sensors.

FIG. 33 illustrates intersection capacitive sensors in combination with the traffic light illustrated by FIG. 31.

FIG. 34 shows a thin film capacitive touch sensor with a solid fill pattern.

FIG. 35 shows a 50% fill pattern capacitive touch sensor.

FIG. 36 shows a 35% fill pattern capacitive touch sensor.

FIG. 37 shows a side view of a thin film capacitive touch sensor similar to those in FIGS. 34-36.

FIG. 38 illustrates a first method of combining thin film capacitive touch sensors with printed art.

FIG. 39 illustrates a second method of combining thin film capacitive touch sensors with printed art.

FIG. 40 illustrates a one-sided thin film capacitive touch sensor with a conductive ground plane layer.

FIG. 41 illustrates a one-sided thin film capacitive touch sensor with an alternative ground plane configuration.

FIG. 42 shows another view of the one-sided thin film capacitive touch sensor of FIG. 41.

FIG. 43 shows a side view of one-sided thin film capacitive touch sensor including an air gap layer for shielding.

FIG. 44 shows a side view of one-sided thin film capacitive touch sensor including an air gap layer for shielding.

FIG. 45 shows a side view of a one-sided thin film capacitive touch sensor including a thick separating material.

FIG. 46 shows a one-sided thin film capacitive touch sensor with air gap layer provided by a corrugated structure.

FIG. 47 illustrates an interactive board game embodiment.

FIG. 48 illustrates a board game embodiment constructed with a thin film capacitive touch sensors printed on the backside (underside) of a printed art layer.

FIG. 49 illustrates an interactive board game embodiment with a lattice structure to provide an air gap layer.

### DETAILED DESCRIPTION

Before beginning a detailed description of the subject invention, mention of the following is in order. When appropriate, like reference materials and characters are used to designate identical, corresponding, or similar components in differing figure drawings. The figure drawings associated with this disclosure typically are not drawn with dimensional accuracy to scale, i.e., such drawings have been drafted with a focus on clarity of viewing and understanding rather than dimensional accuracy.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

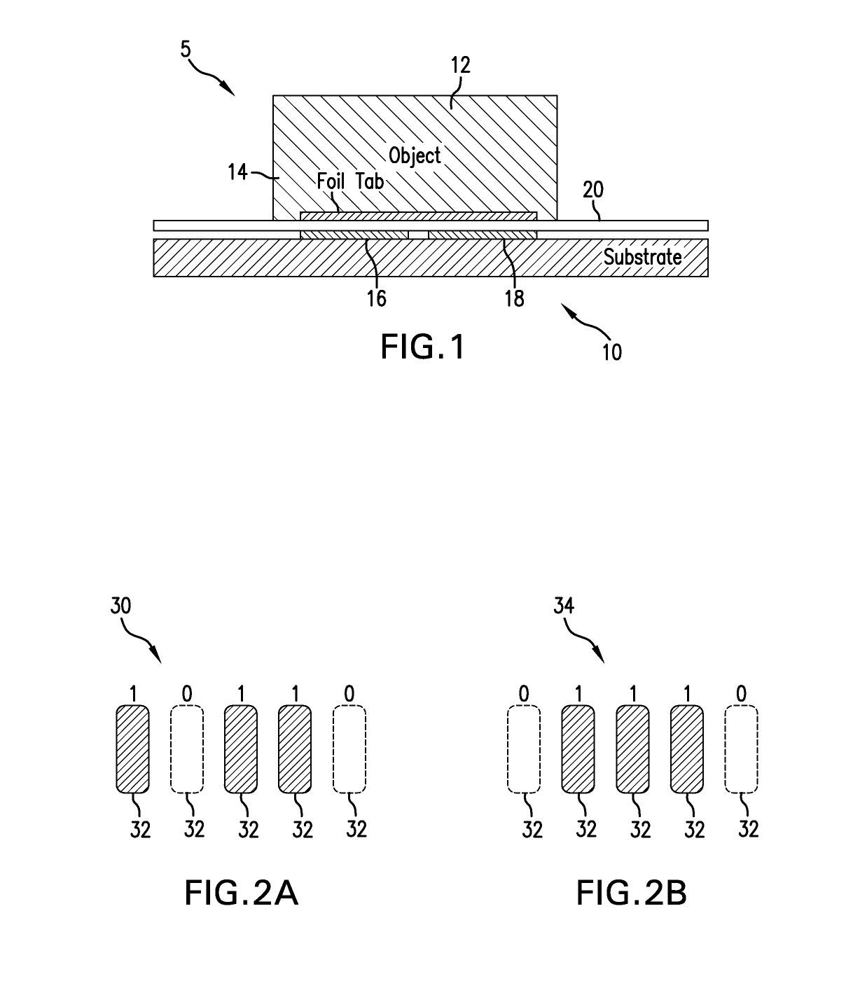

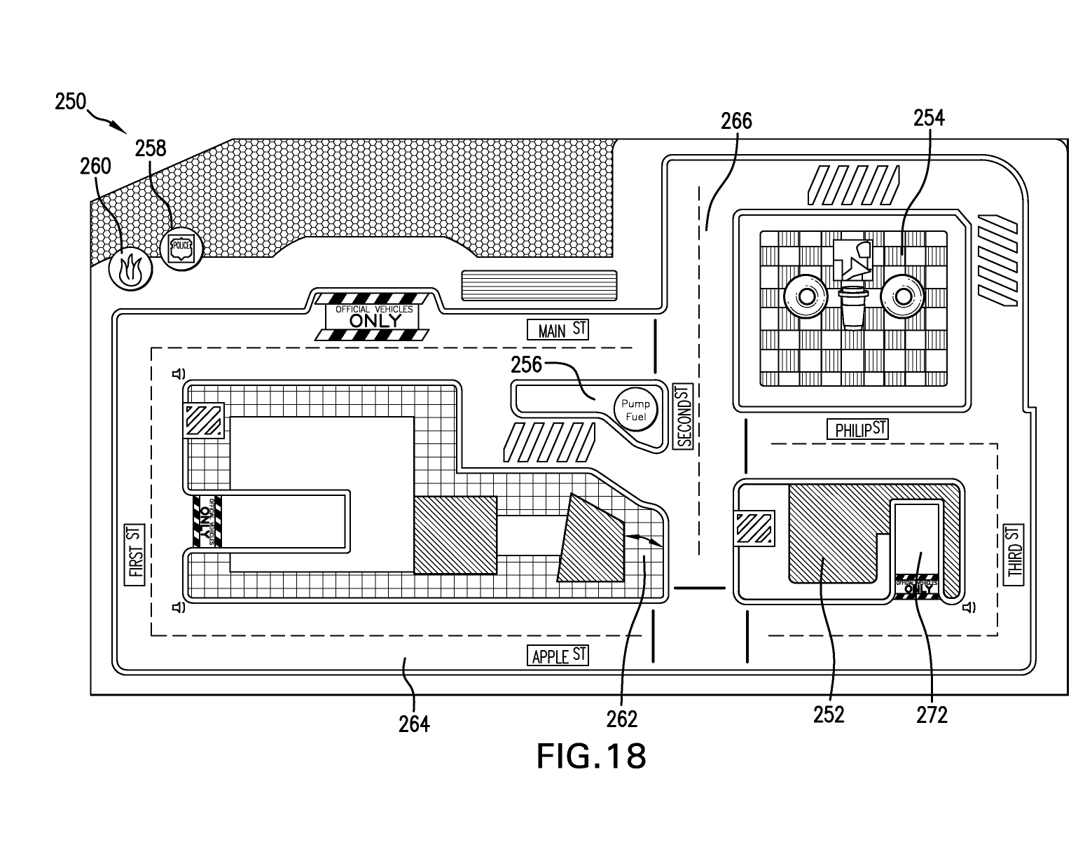

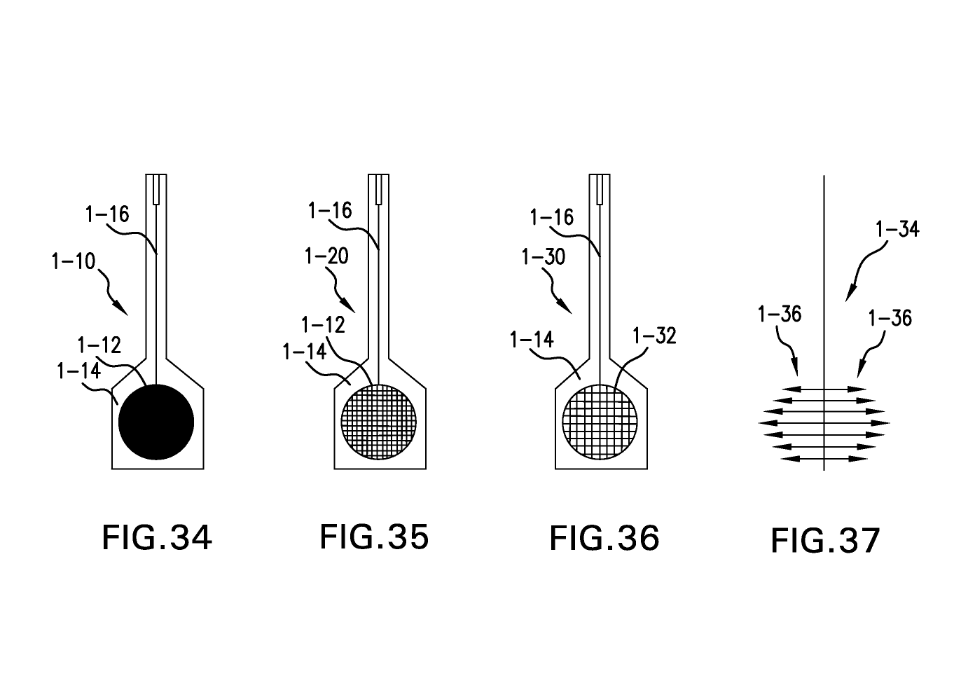

FIGS. 1-49 illustrate embodiments of interactive play sets with capacitive sensors. In some embodiments, the capacitive sensors are thin film capacitive sensors. The relative low cost and simplicity/elegance of the capacitive sensors enables play sets, such as a toy vehicle play set, to include human touch and object sensitive functionality and interaction. Play objects may include toy vehicles, toy aircraft, figurines, toy buildings, etc. FIGS. 34-49 generally illustrate the construction of thin film capacitive sensors in general, then capacitive touch sensors specifically and their application to the construction of an interactive play set. FIGS. 1-7 generally illustrate the construction of capacitive sensors for detection and identification of small objects and their application to the construction of an interactive play set. FIGS. 8-17 generally illustrate object detection and identification for the play set. FIGS. 18-32 generally illustrate the play set or sensor layout and design.

Embodiments of the interactive play system include capacitive sensors in a variety of applications. Some capacitive sensors may be used as touch sensors (for example, a finger touch). Other capacitive sensors may be used to detect the presence of small objects such as game pieces, figures, and cards. These objects may be made of a conductive material or may have conductive material such as metal foil applied to or embedded in them.

### Capacitive Touch Sensors

Many existing sample capacitive design kits available from manufacturers use printed circuit boards to create and connect thin film capacitive touch sensors. This approach is too expensive and cumbersome for most low-cost applications (e.g., game, toy, book, and greeting card, among others). A low-cost alternative is to manufacture thin film capacitive touch sensors (thin compared to printed circuit boards). One method of manufacturing thin film capacitive touch sensors is to print the elements of the capacitors with conductive ink onto a thin film substrate using a screen printing technique. The thin film substrate may be a sheet of material like plastic (e.g., polyester) or paper. In addition to being lower cost than a printed circuit board, thin film substrates such as polyester or paper are more flexible.

FIGS. 34-37 illustrate several embodiments of thin film capacitive touch sensors with different fill patterns. FIG. 34 shows a thin film capacitive touch sensor 1-10 with a solid fill pattern. The thin film capacitive touch sensor 1-10 has a thin film substrate 1-14 and a capacitive element 1-12. The capacitive element 1-12 is made of conductive ink deposited without porosity on the thin film substrate 1-14, giving it a solid fill pattern. In this embodiment, the conductive ink is deposited using a screen printing technique, but in other embodiments, other techniques may be used. The thin film capacitive touch sensor 1-10 also has an interconnect 1-16, configured to electrically connect the capacitive element 1-12 to circuits outside of the thin film capacitive touch sensor 1-10. In this embodiment, the interconnect 1-16 is also conductive ink deposed on the thin film substrate 1-14. Capacitive elements and interconnects are collectively referred to herein as “conductive pathways.”

The conductive ink used generally includes a polymer and a metal and/or carbon conductive material. For example, the polymer may include powdered and/or flaked silver, gold, copper, nickel, and/or aluminum. In some embodiments, the conductive pathways range from less than 100 Ohms to 8K Ohms resistance, depending on their material composition and configuration. Conductive ink with less conductive material may be less expensive, but may exhibit greater resistivity. Conductive ink with a greater amount of conductive material may be more expensive, but may exhibit decreased resistivity.

The cost of capacitive touch sensors may be mitigated by substituting the capacitive element 1-12 with the solid fill pattern shown in FIG. 34 with a capacitive element having a partial fill pattern, resulting in a partial fill pattern capacitive touch sensor. The partial fill pattern capacitive element is porous, resulting in an area of thin film substrate under the partial fill pattern capacitive element having less than complete conductive ink coverage. However, the partial fill pattern capacitive element is continuous, so that electrical charges can flow to all parts of the element.

As examples of partial fill pattern capacitive touch sensors, FIG. 35 shows a 50% fill pattern capacitive touch sensor 1-20 and FIG. 36 shows a 35% fill pattern capacitive touch sensor 1-30. In FIG. 35, the 50% fill pattern capacitive touch sensor 1-20 has a 50% fill pattern capacitive element 1-22, meaning only 50% of a thin film substrate 1-14 under the 50% fill pattern capacitive element 1-22 is covered by conductive material. In FIG. 36, the 35% fill pattern capacitive touch sensor 1-30 has a 35% fill pattern capacitive element 1-32, meaning only 35% of a thin film substrate 1-14 under the 35% fill pattern capacitive element 1-32 is covered by conductive material. As the percentage of fill pattern decreases, the capacitance of the capacitive touch sensor is reduced, but the area covered by the capacitive touch sensor remains the same. For many applications that detect human finger touches, 35% and greater fill may decrease the cost of the capacitive touch sensor substantially without suffering significant performance loss. Thus a capacitive element can remain a large target for a user to touch, but with reduced conductive material.

In the embodiments shown in FIGS. 34-36, the partial fill pattern shown is a rectilinear grid of crisscrossed horizontal and vertical lines intersecting at right angles. However, other partial fill patterns may be used, such as a regular pattern of small circular pores. For convenience, herein “grid” shall mean any partial fill pattern.

FIG. 37 shows a side view of a thin film capacitive touch sensor 1-34 like those discussed regarding FIGS. 34-36. When charged, a capacitive field 1-36 extends from the front and back of the thin film capacitive touch sensor 1-34. The capacitive field 1-36 is an electrical field that will interact with nearby conductive objects, such as a human finger, changing the effective capacitance of the thin film capacitive touch sensor 1-34. The thin film capacitive touch sensor 1-34 can be said to be “two-sided,” since interaction with the capacitive field 1-36 on either the front side or back side can be detected via the change in effective capacitance.

Alternately, instead of screen printed conductive ink, one or more of the conductive pathways may be formed from thin copper or other metal layers. For example, one or more of the conductive pathways may be formed from a thin copper sheet that is photo-lithographically patterned and etched to form one or more of the conductive pathways, i.e. the capacitive element and/or related interconnects. Capacitive elements with partial fill patterns may be etched from thin metal as well. The copper conductive pathways may be laminated to a flexible substrate layer. Accordingly, both the copper and conductive ink conductive pathway embodiments, or a combination thereof, may form at least part of a flexible circuit (e.g., a “flex” circuit).

In some embodiments, any additional electronics that couple to the one or more capacitive elements and related interconnects may be at least in part be included on the same flexible substrate as the one or more thin film capacitive touch sensors. Alternately, at least some of the additional electronics may be included on a separate substrate. For example, at least some of the electronics may be included on a separate printed circuit board. Multiple circuits on multiple substrates may be electrically coupled together with any electrical coupling devices and/or methods known in the art.

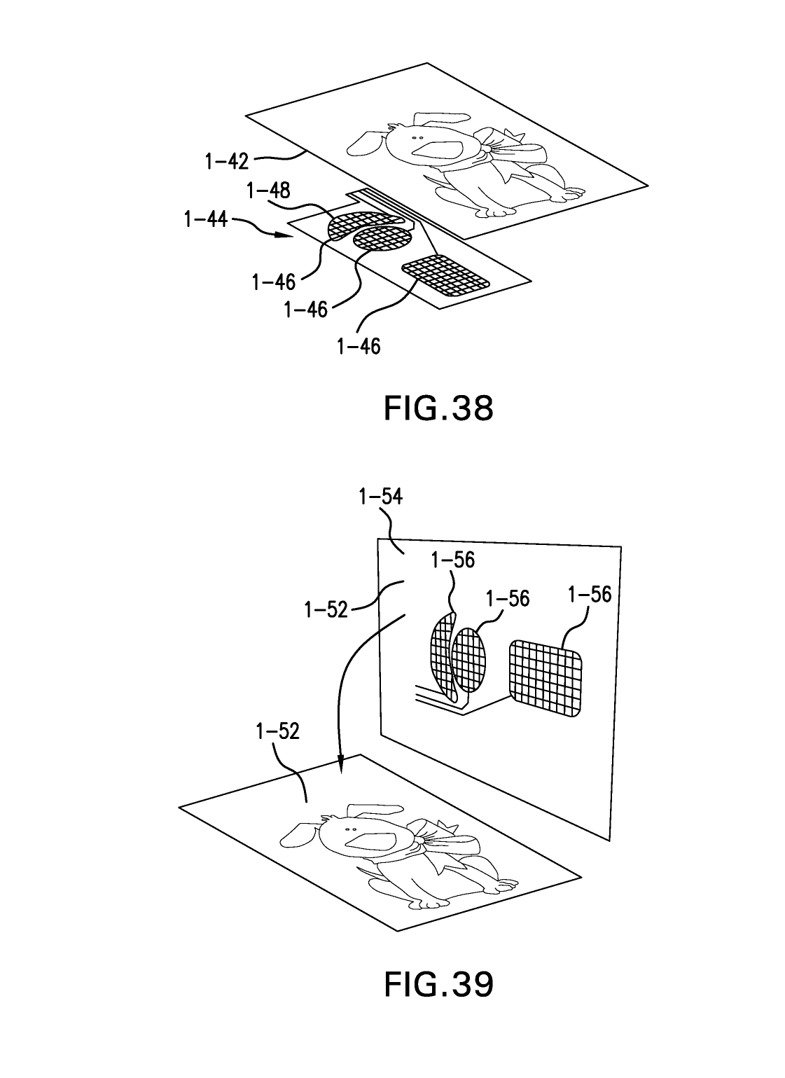

FIGS. 38 and 39 illustrate methods of combining thin film capacitive touch sensors with printed art. FIG. 38 illustrates a first method of combining thin film capacitive touch sensors with printed art. A capacitive touch sensor layer 1-44 is coupled to a printed art layer 1-42 by lamination, gluing or other process. This capacitive touch sensor layer 1-44 comprises one or more (three in the embodiment shown) capacitive elements 1-46 deposed on a thin film substrate 1-48 (e.g. paper or plastic), forming one or more thin film capacitive touch sensors, similar in construction to those described in the discussion regarding FIGS. 34-37. In this embodiment, the capacitive elements 1-46 are conductive ink deposed on the thin film substrate 1-48 using a screen printing process. In other embodiments, the capacitive elements 1-46 may be made with lithography out of metal foil, or some other method.

FIG. 39 illustrates a second method of combining thin film capacitive touch sensors with printed art. Here, a printed art layer 1-52 comprises art printed directly onto a thin film substrate 1-58. One or more capacitive elements 1-56 are deposed onto the same thin film substrate 1-58 as well, forming a capacitive touch sensor layer 1-54. In some embodiments, an opaque layer of non-conductive ink may be printed on the printed art layer 1-52 over the art and the capacitive elements 1-56 printed over the opaque layer. This opaque layer substantially prevents the conductive pathways and/or product supporting structure from showing through the thin film substrate 1-58. In other embodiments, the capacitive elements 1-56 are printed directly over the printed art layer 1-52 without an opaque layer.

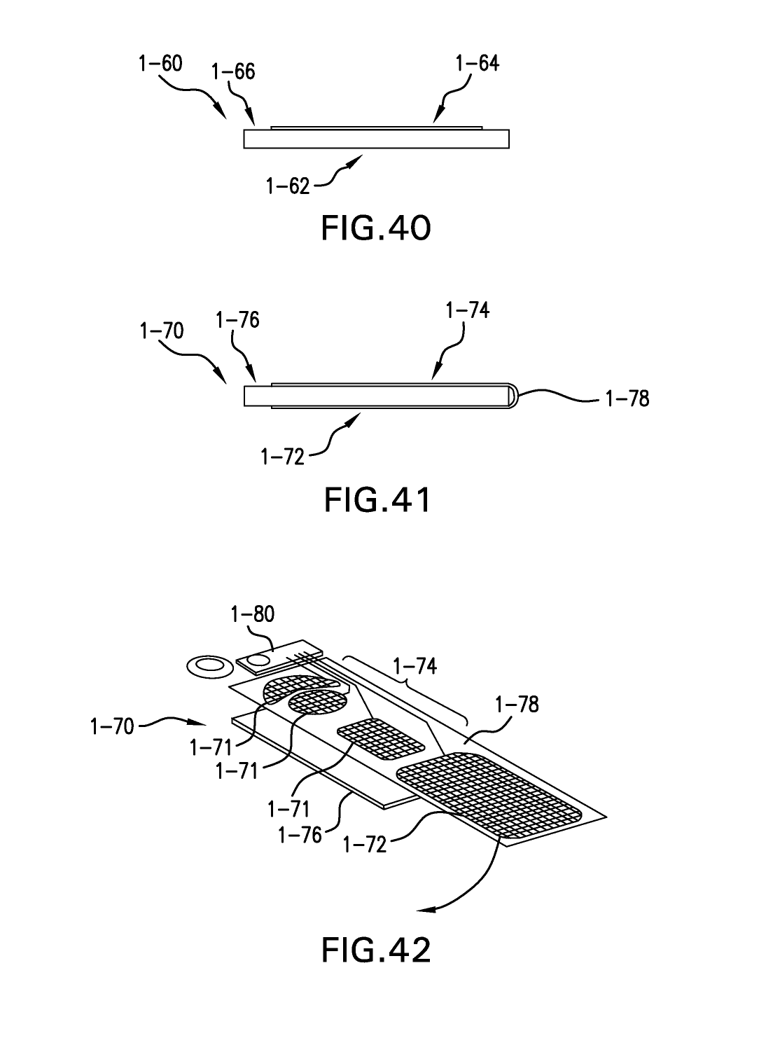

FIGS. 40-42 illustrate embodiments of one-sided thin film capacitive touch sensors with conductive ground plane layers to substantially mitigate the two-sided functionality of the thin film capacitive touch sensors described by the discussion regarding FIGS. 34-39. In particular for games, toys, books, and greeting cards that may be handheld, one-sided thin film capacitive touch sensors may improve the ability with which a user may properly interact with the games, toys, books, and greeting cards.

FIG. 40 illustrates a one-sided thin film capacitive touch sensor 1-60 with a conductive ground plane layer 1-62. The one-sided thin film capacitive touch sensor 1-60 comprises a capacitive touch sensor layer 1-64 separated from the conductive ground plane layer 1-62 with a separation layer 1-66. The capacitive touch sensor layer 1-64 is a two-sided thin film capacitive touch sensor as described in the discussion regarding FIGS. 34-37. In this embodiment, the separation layer 1-66 is a thin sheet of dielectric material like paper or plastic. In one embodiment, the conductive ground plane layer 1-62 is constructed by mounting a very thin sheet of conductive material such as aluminum foil or screen printed conductive ink on the backside of the separation layer 1-66. The separation between the capacitive touch sensor layer 1-64 and the conductive ground plane layer 1-62 is a minimum of 0.5 mm. Any separation less than 0.5 mm causes base capacitance of the capacitive touch sensor layer 1-64 to increase dramatically, so much so that any touch by a human finger will not change the effective capacitance of the capacitive touch sensor layer 1-64, rendering such touches undetectable. Any separation less than 0.5 mm may cause the one-sided thin film capacitive touch sensor 1-60 to experience large changes in base capacitance when the capacitive touch sensor layer 1-64 experiences mechanical bending. Simply flexing the one-sided thin film capacitive touch sensor 1-60 may lead to fluctuations in effective capacitance larger than those typically seen when one-sided thin film capacitive touch sensor 1-60 is touched by a human finger, degrading the touch sensitivity of the one-sided thin film capacitive touch sensor 1-60.

FIG. 41 illustrates a one-sided thin film capacitive touch sensor 1-70 with an alternative ground plane configuration. The one-sided thin film capacitive touch sensor 1-70 has one or more capacitive elements 1-71 (not visible this view, see FIG. 42) deposed on a thin film 1-78 to form a capacitive touch sensor layer 1-74 and a conductive ground plane layer 1-72 deposed on the same thin film 1-78, the thin film 1-78 wrapped around a separation layer 1-76. In this embodiment, the separation layer 1-76 is a thin sheet of dielectric material like paper or plastic.

FIG. 42 shows another view of the one-sided thin film capacitive touch sensor 1-70 of FIG. 41, showing the capacitive elements 1-71 and conductive ground plane layer 1-72 deposed on the same thin film 1-78, the thin film 1-78 laid flat, but configured to be wrapped around separation layer 1-76 (see FIG. 42 with arrow showing wrapping action). The conductive ground plane layer 1-72 may be a grid or solid fill pattern, as described above regarding FIGS. 34-37. In some embodiments, capacitive elements 1-71 and the conductive ground plane layer 1-72 may be formed from the same conductive material (e.g., conductive ink) and substantially simultaneously (e.g., from the same patterned printing screen). Also shown are electronics 1-80 for measuring the effective capacitance of the one-sided thin film capacitive touch sensor 1-70.

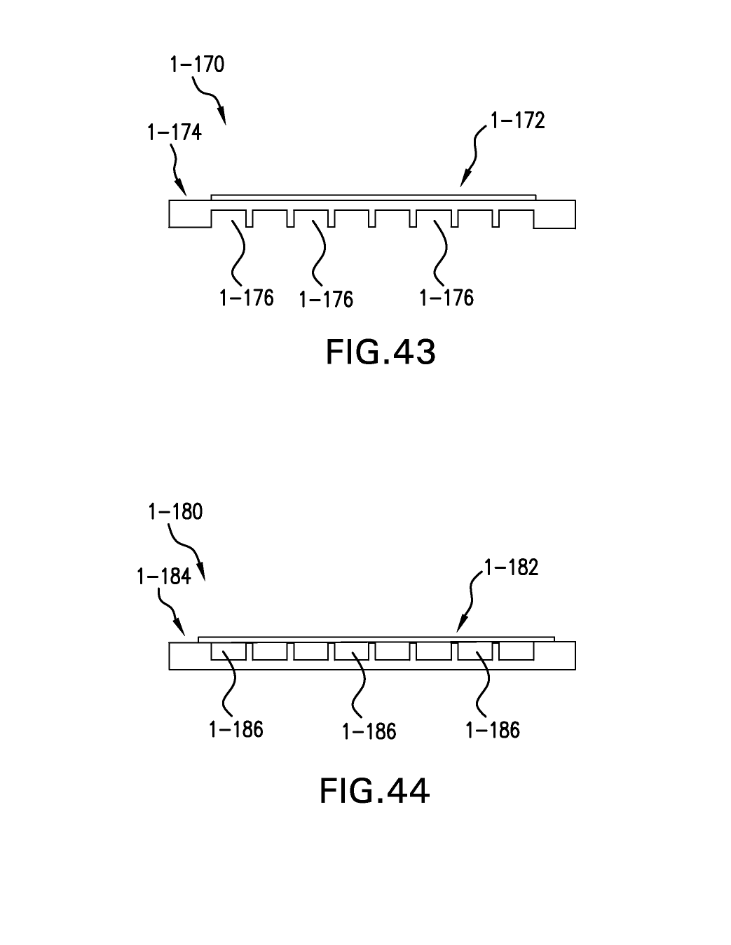

FIGS. 43-46 illustrate embodiments including an air gap layer or a layer of non-conducting material to substantially mitigate the two-sided functionality of the thin film capacitive touch sensors described by FIGS. 1-8 while maintaining the substantially low cost and simple construction. In particular for games, toys, books, and greeting cards that may be handheld, the one-sided functionality of the thin film capacitive touch sensors may improve the ability with which a user may properly interact with the games, toys, books, and greeting cards.

As an alternate approach to including a conductive ground plane layer shield to form a substantially one-sided capacitive sensor, other embodiments use materials with very low dielectric constants as a shield for one side of the capacitive sensor. More specifically, one very inexpensive material with a very low dielectric constant is air. The inclusion of an air gap layer will lower the capacitive sensitivity on the air gap layer side of the capacitive sensor. Nevertheless, a capacitive field may still be triggered by proximity though the air depending on the configuration of the capacitive sensor. Accordingly, one-sided thin film capacitive touch sensors with an air gap layer should be tested for any potential application to determine their suitability. For example, there is a relationship between the size/area of a touch capacitive sensor and its proximity sensitivity through air. Generally, larger capacitive touch sensors are more sensitive and may require a thicker air-gap for proper shielding. As a guideline, the air gap layer should be at least the thickness of any overlay material on top of the capacitive elements. For example, a configuration that includes a thin film capacitive touch sensor 2 mil thick (capacitive elements printed in conductive ink on bottom), an printed art layer 10 mil thick and a 5 mil layer of glue totals an overlay of 17 mil over the capacitive elements. This would suggest an air gap layer of at least a 17 mil (˜0.5 mm). For capacitive elements less than 2 square inches in area, an air gap layer of five times the overlay thickness have proven to be sufficient.

FIG. 43 shows a side view of one-sided thin film capacitive touch sensor 1-170 including an air gap layer 1-176 for shielding. The one-sided thin film capacitive touch sensor 1-170 includes a capacitive touch sensor layer 1-172 mounted to a separating base 1-174. The separating base 1-174 has a molded or cut pattern to create the air gap layer 1-176 on a side of the separating base 1-174 opposite the capacitive touch sensor layer 1-172. The separating base 1-174 prevents foreign objects, such as a human finger, from entering the air gap layer 1-176 and changing the effective capacitance of a sensor in the capacitive touch sensor layer 1-172. The air gap layer 1-176 mitigates sensitivity to touch from the bottom, as explained above. In this embodiment the separating base 1-174 has a lattice structure, but in other embodiments, structures with other geometries, such as a corrugation structure, may be used to create the air gap layer 1-176.

FIG. 44 shows a side view of one-sided thin film capacitive touch sensor 1-180 including an air gap layer 1-186 for shielding. The one-sided thin film capacitive touch sensor 1-180 includes a capacitive touch sensor layer 1-182 mounted to a separating base 1-184. The separating base 1-184 has a molded or cut pattern to create the air gap layer 1-186 on a side of the separating base 1-184 closest to the capacitive touch sensor layer 1-182. The separating base 1-184 prevents foreign objects, such as a human finger, from entering the air gap layer 1-186 and changing the effective capacitance of a sensor in the capacitive touch sensor layer 1-182. The air gap layer 1-186 mitigates sensitivity to touch from the bottom. In this embodiment the separating base 1-184 has a lattice structure, but in other embodiments, structures with other geometries, such as a corrugation structure, may be used to create the air gap layer 1-186.

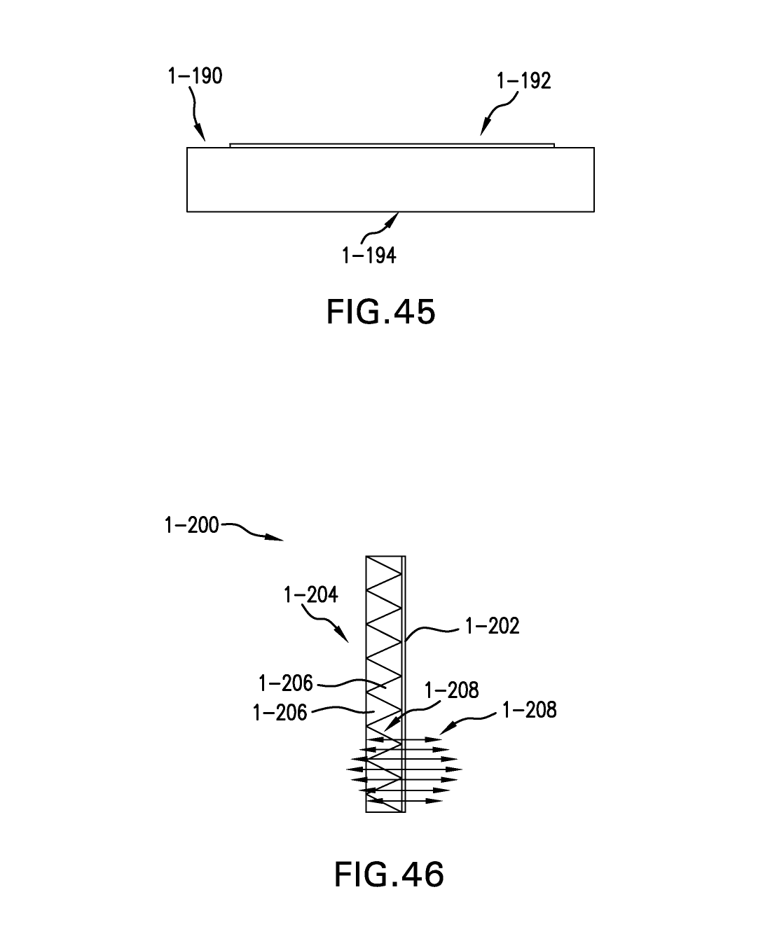

FIG. 45 shows a side view of a one-sided thin film capacitive touch sensor 1-190 including a thick separating material 1-194. The one-sided thin film capacitive touch sensor 1-190 includes a capacitive touch sensor layer 1 192 mounted to the thick separating material 1-194. The thick separating material 1-194 is a non-conducting material such as plastic or cardboard. The one-sided thin film capacitive touch sensor 1-190 reduces or eliminates sensitivity to touches on the back side of the capacitive touch sensor layer 1-192 with thick separating material 1-194. The thick separating material 1-194 forces such touches further from the back side of the capacitive touch sensor layer 1-192 and accordingly reduces change to effective capacitance of the capacitive touch sensor layer 1-192 during such touches.

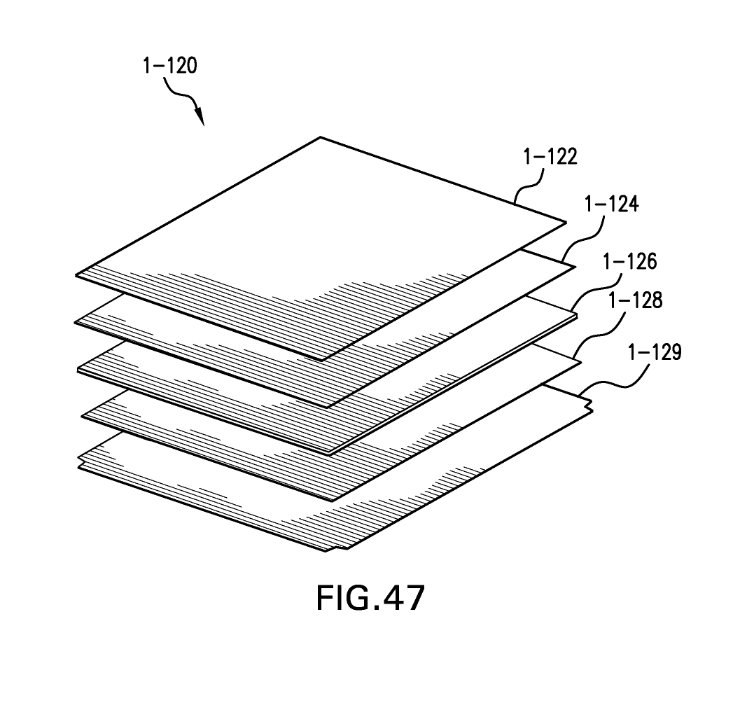

FIG. 46 shows a one-sided thin film capacitive touch sensor 1-200 with air gap layer 1-206 provided by a corrugated structure 1-204, such as corrugated cardboard or similar materials. The thin film capacitive touch sensor 1-200 has a capacitive touch sensor layer 1-202 mounted on the corrugated structure 1-204, which mitigates sensitivity to touches on a side of the capacitive touch sensor layer 1-202 nearest the corrugated structure 1-204 (i.e. the back side) due to diminished strength of a capacitive field 1-208 generated by the capacitive touch sensor layer 1-202 after passing through the corrugated structure 1-204. Such corrugated structures, in particular with corrugated cardboard and the like, are inexpensive construction materials common to games and toys.

Accordingly, these air gap layer embodiments of one-sided thin film capacitive touch sensors may be easily and inexpensively integrated into games, toys, and the like to add interactive and other computer-based features. For example, as will be explained in more detail below, a conductive ground plane layer may be replaced by a lattice structure or the like to provide substantially one-sided functionality for capacitive touch sensors.

FIG. 47 illustrates an interactive board game 1-120 embodiment. The interactive board game 1-120 includes a printed art layer 1-122, a capacitive touch sensor layer 1-124, a separation layer 1-126 (e.g. chip board), a conductive ground plane layer 1-128 (e.g., a metal foil and/or metal foil paper), and a game board back wrap 1-129. The capacitive touch sensor layer 1-124 is separated from the conductive ground plane layer 1-128 by the separation layer's 1-126 approximately 2.0 mm thickness. This provides more than the 0.5 mm separation between the capacitive touch sensor layer 1-124 and the conductive ground plane layer 1-128 required for good one-sided sensor characteristics.

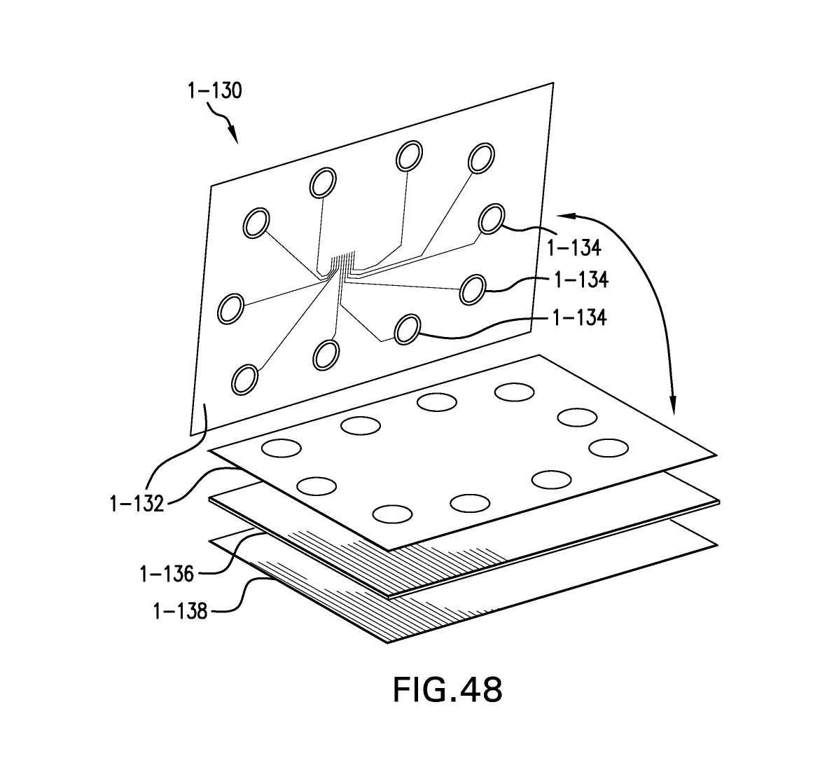

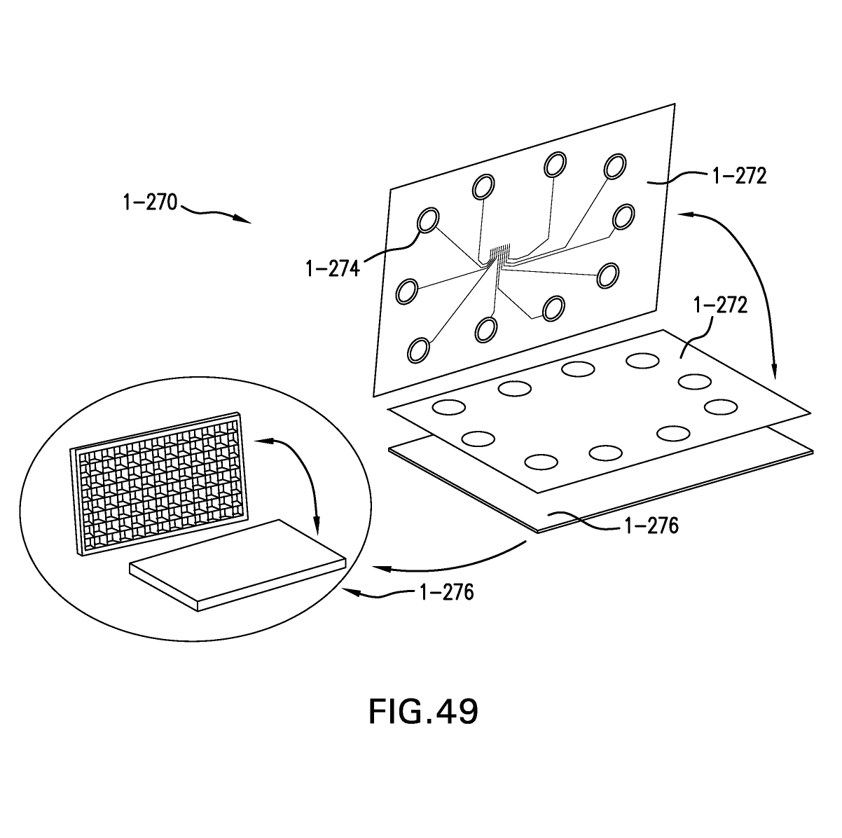

FIG. 48 illustrates a board game 1-130 embodiment constructed with a thin film capacitive touch sensors 1-134 printed on the backside (underside) of a printed art layer 1-132. Similar to the configuration of layers illustrated by FIG. 49, the thin film capacitive touch sensors 1-134 may be separated from a conductive ground plane layer 1-138 by a separation layer 1-136 (such as a chip board) that is approximately 2.0 mm thick. This provides more than the 0.5 mm separation required for good one-sided sensor characteristics.

FIG. 49 illustrates an interactive board game 1-270 embodiment with a lattice structure to provide an air gap layer. The interactive board game 1-270 includes a printed art layer 1-272, a capacitive touch sensor layer 1-274, and a separating base 1-276. In this embodiment, a plastic board is used as the separating base 1-276. The separating base 1-276 may include a molded grid and/or lattice structure on either the bottom side of the separating base 1-276 or on a side of the separating base 1-276 adjacent the capacitive touch sensor layer 1-274 to create an air gap layer adjacent the capacitive touch sensor layer 1-274. In this embodiment, the printed art layer 1-272 includes the capacitive touch sensor layer 1-274. In other embodiments, printed art layer 1-272 and the capacitive touch sensor layer 1-274 may be separate layers as described above.

Applying the teaching discussed above, play set art details may be printed in full color on paper or plastic sheets, allowing the play set to be overall very thin. Depending on overall configuration of the play set platform and plastic base, the play set construction may include at least one ground plane layer to shield at least a portion of the play set elements and at least one air-gap and/or air gap layer to shield at least another portion of the play set elements. The inclusion of the conductive ground plane behind at least some play set elements eliminates the need for a plastic housing in that region, thereby enabling that region of the play set to be substantially thin. Alternately, the plastic housing forms an air gap or lattice of air gaps behind the capacitive sensors in thicker regions of the play set that include the plastic housing or enclosure. Accordingly, the overall shape of the play set of an embodiment may be flexible as the shape of the play set platform and the plastic base or enclosure need not substantially match. Said differently, capacitive sensors adjacent only the play set platform (and shielded by a conductive ground plane only) may operate substantially similarly to capacitive sensors adjacent the play set platform and the plastic base (and shielded by an air gap, conductive ground plane, or a combination thereof).

The combination of the air gap provided in and/or formed by the plastic housing with the conductive ground plane behind the respective capacitive sensor layers may mitigate the capacitive sensor sensitivity to substantially prevent false and/or unintentional capacitive sensor triggering in each play set region and/or element. In an embodiment, the printed art layer and the capacitive sensor layer may be separate. In an alternate embodiment, the capacitive sensor layer may be combined with the printed art layer, for example by the capacitive sensors being screen printed or otherwise formed on the underside or backside of the printed art layer.

### Capacitive Sensors for Detection and Identification of Small Objects

Capacitive sensors designed for use exclusively as touch sensors may not typically perform well in detection of other objects. As noted, capacitive sensing works by detecting and measuring changes in capacitance between a sensor—typically a flat metal plate—and another point in the system, often the system ground. Accordingly, systems may detect touch or objects by detecting and/or measuring changes in capacitance between one or more sensor plates and the system ground. Touch sensors meant to detect contact by a finger or hand may include only a small sensor plate that covers the touch sensitive area as the relatively large size and surface area of the human body may provide significant capacitive coupling to the system ground (or to any other unshielded node in the system). When a person touches the sensor, the capacitive coupling between the sensor and the person's body may be increased. This capacitance in series with the body-to-ground capacitance increases the sensor-to-ground capacitance that may thereafter be detected and/or measured. The small size and surface area of the objects, for example vehicles, that may be detected by the vehicle system of an embodiment may benefit from a capacitive sensor design different from a touch capacitive sensor. For example, the smaller objects (e.g., toy vehicles) may have poor capacitive coupling to the system ground unless placed in very close proximity to it, so the capacitive sensors designed to detect the small objects may include a plate connected to ground in addition to the sensor plate.

FIG. 1 illustrates a cross section of a sensor system 5 with a capacitive sensor 10 and a conductive object 12 placed over the capacitive sensor 10. In most embodiments, the conductive object 12 is mostly non-conductive material with a conductive tab 14 deposed in the conductive object 12. The capacitive sensor 12 comprises a sensor pad 16 and a ground pad 18. The sensor pad 16 and ground pad 18 are adjacent to each other such that the conductive object 12 may overlap both the sensor pad 16 and ground pad 18 and provide significant capacitive coupling between them. The sensor-to-object capacitance in series with the object-to-ground capacitance increases the sensor-to-ground capacitance, which may be detected and measured by a detection circuit.

The conductive tab 14 is embedded in or applied to the conductive object 12 and may be a thin foil or thicker plate. The sensor pad 16 and ground pad 18 may be constructed by printing conductive ink on a thin plastic substrate or on part of a printed circuit board. The sensor pad 16 and ground pad 18 in each pair are positioned adjacent each other, in a location where both will be covered by the conductive object 12 when the conductive object is place over the capacitive sensor 10. In most embodiments, the sensor pad 16 and ground pad 18 will all be placed in a plane, such as on a flat horizontal structure, but this is not required.

The sensor pad 16 and ground pad 18 may typically be covered with a layer of dielectric material 520 so that they do not make direct electrical contact with the conductive object 12. Further, the conductive tab 14 in the conductive object 12 may be exposed on the surface of the conductive object 12 or embedded within. There may numerous methods for fabricating the conductive tab 14 and integrating it onto the conductive object 12.

The sensor pad 16 and ground pad 18 are oriented such that their capacitive coupling is substantially reduced with no conductive object 12 present. When the conductive object 12 is placed over the sensor pad 16 and ground pad 18, capacitive coupling between the conductive object 12 and both the sensor pad 16 and ground pad 18 is introduced. This arrangement forms a pair of capacitors—a sensor-pad-to-tab and tab-to-ground—for which the series combination greatly increases the sensor-to-ground capacitance. The increase in the sensor-to-ground capacitance may then be detected and/or measured by a capacitance measuring circuit (not shown).

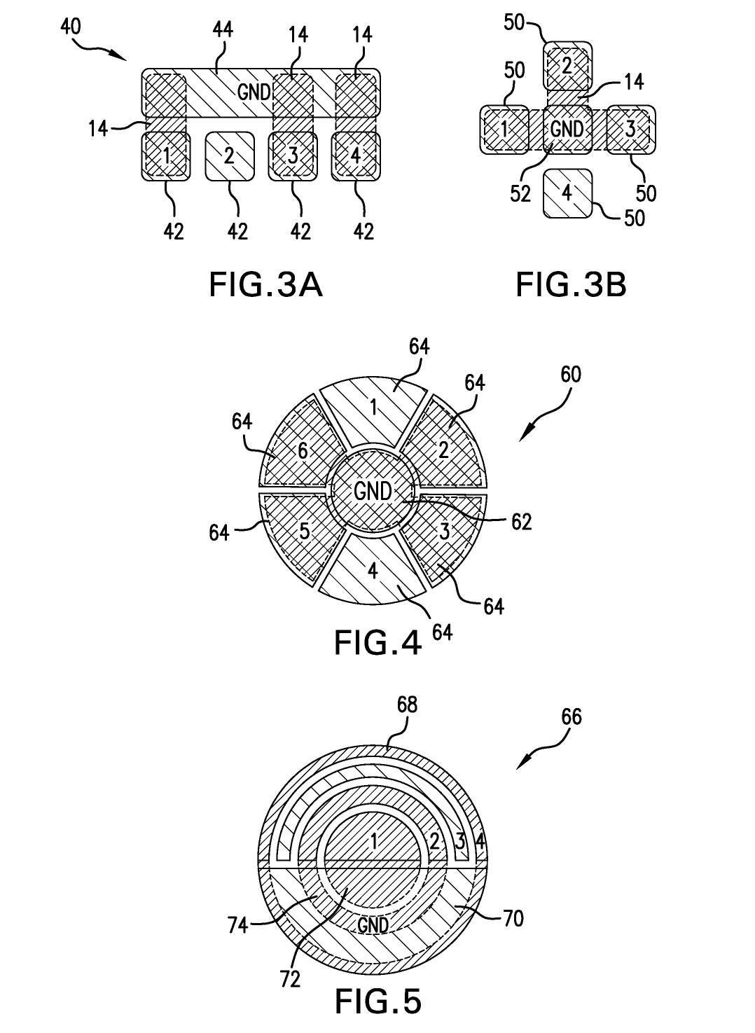

FIGS. 2A, 2B, 2C and 3A show a sensor system for detecting a numerical value encoded on an object. FIGS. 2A and 2B illustrate binary tab patterns (30 and 34) used to identify an object and FIG. 3A shows a sensor array 40 for detecting these tab patterns. The binary tab patterns 30 and 34 each comprise multiple tab locations 32 in an object (not shown). A binary number may be encoded by the presence (indicated by a 1 in FIGS. 2A and 2B) or absence (indicated by a 0) of a conductive tab 14 at each of the tab locations 32. FIGS. 2A and 2B specifically illustrate two binary tab patterns. The tab pattern in FIG. 2A represents a binary 10110 (or 22) and the tab pattern in FIG. 2B represents binary 01110 (or 14). The theoretical number of unique patterns in a system with n tab locations 32 at each location is 2̂n. In practice, one of these patterns includes no tabs, which cannot be distinguished from when no object is present over the sensor array 40, so the total must be reduced to 2̂n−1. Accordingly, four tab locations 32 would allow fifteen different patterns; five tab locations 32 would allow thirty-one patterns, and so on.

The presence or absence of a tab at location in the object is detected by a corresponding capacitive sensor 42 in the sensor array 40 when the object is placed over the sensor array 40 such that the tab locations 32 are each over their corresponding capacitive sensor 42. In the embodiment shown, the sensor array 40 has a common ground pad 44 for all the capacitive sensors 42 in the sensory array 40. In other embodiments, the each capacitive sensor 42 has its own ground pad.

The type of sensor systems shown in FIGS. 2A, 2B, and 3A may also be used for multi-level (instead of binary) sensing by varying the size or placement of the tabs. In an m-level, system, the each tab location could have one of m−1 different sized tabs or no tab.

The sensor array 40 is design neutral, in that the shape and configuration of the sensors 42 and tab locations 32 is independent of the encoding method. Thus other sensor arrays may be made with different topologies. FIG. 3B shows a sensor array 48 with a cross topology. The cross topology sensor array 48 has sensors 50 clustered around a central ground pad 52. This embodiment may encode a binary value with a single tab that covers the ground pad 52 and extends to the desired sensors 50. FIG. 4 illustrates a circular sensor array 60 for binary sensing. The circular sensor array 60 has a shared ground pad 62 and multiple sensor pads 64. Similarly, FIG. 5 illustrates an arcuate sensor array 66. The arcuate sensor array 66 has one or more arcuate sensor pads 68 and an arcuate ground pad 70. The arcuate sensor pads 68 correspond with circular tabs 72 or annular conductive tabs 74 in an object (not shown) when the object is properly positioned over the arcuate sensor array 66. The arcuate sensor array 66 can detect and decode a value encoded in the tabs of the object regardless of the rotational alignment of the object over the arcuate sensor array 66.

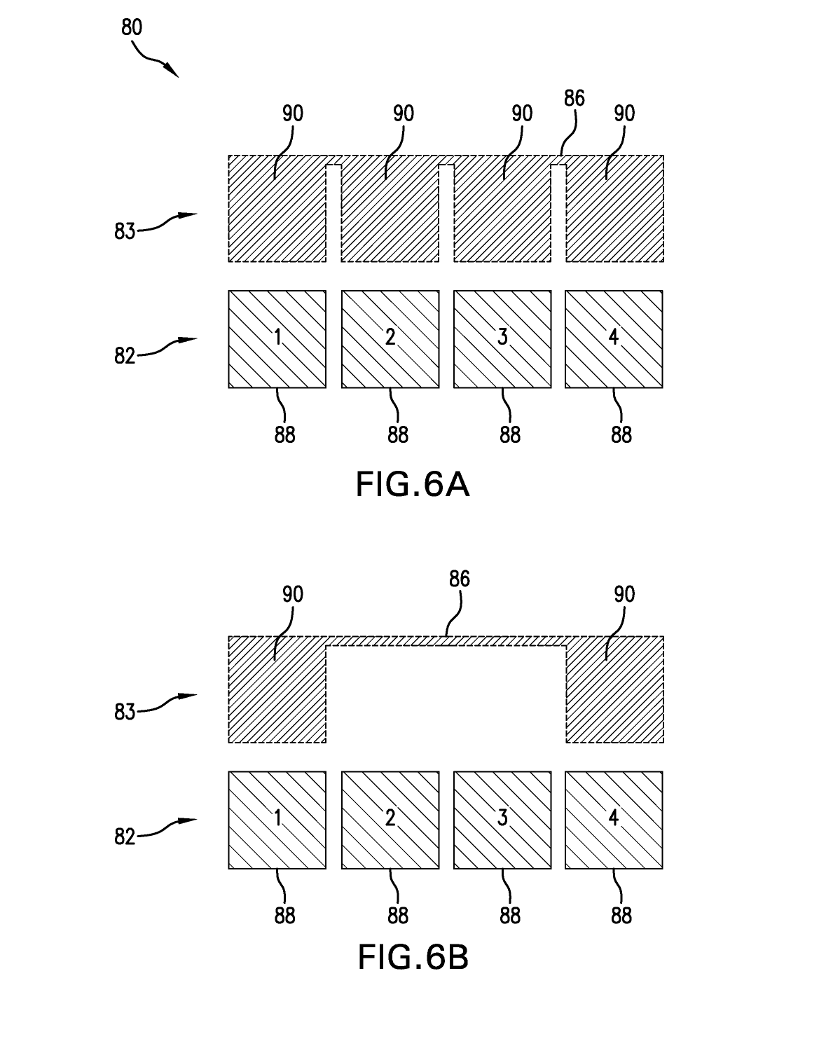

FIGS. 6A and 6B illustrate a sensor system 80 with a switching sensor array 82 and a connected tab array 83 deposed in an object to be identified (object not shown). The switching sensor array 82 has sensor pads 88 only and no ground pads. The connected tab array 83 has tab locations 84 that are interconnected with a conductor 86. At least two of the tab locations 84 have conducting tabs 90. The conductor 86 is preferably located on the object relative to the tab locations 84 such that it does not overlap any sensor pads 88 to minimize unwanted capacitive coupling. When the object with the connected tab array 86 is properly lined up with the switching sensor array 82 so that the tab locations 84 are over the corresponding sensor pads 88, a numerical value encoded on the object can be read by reading each of the sensor pads 88 in sequence. While the capacitance of each sensor pad 88 is measured, the other sensor pads 88 in the switching sensor array 82 are switched to ground by detection circuitry (not shown). Since the tab locations 84 are interconnected, conducting tabs 90 in other tab locations 88 over one of the sensor pads 88 (which is pulled to ground) couple the conducting tabs 90 to ground, thereby creating a change in capacitance from when the connected tab array 83 is not aligned over the switching sensor array 82. This method offers an advantage over a single-tab approach discussed above as multiple tabs may couple to ground simultaneously and may improve the overall signal performance of the encoding/identification method of an embodiment. However, at least two of the tab locations 84 need to have conducting tabs 90 present for identification to work, as the second tab is required for minimal coupling to ground as the capacitance at the first tab is measured.

The conducting tabs in the described embodiments contain a layer of contiguously conductive material. This material may further be laminated or coated with other non-conductive “protective” materials to help reduce wear and tear. Various tab materials and construction methods are contemplated. In some embodiments, a hot stamp foil, or thin laminated metallic decoration(s) may be added or bonded to objects made of materials such as paper and/or plastic. In other embodiments, a conductive ink pattern may be applied to the surface of an object by screen printing. Similarly, a hot stamp foil or conductive ink sticker may include a hot stamp foil or conductive ink applied to a thin film material such as paper or plastic and then adhered to an object like a sticker. In yet other embodiments, etched, stamped, or cut thin metal plates or strips (e.g., copper, brass, aluminum, or any other metal) may be laminated to other materials (like paper or plastic) and applied to an object as stickers. The metal plates or strips may alternately be applied directly to an object. Further still, an object may be formed from metal with detection tabs molded to extend outwards from the object to create identification patterns.

### Capacitive Sensors Configured to Detect or Identify Play Objects

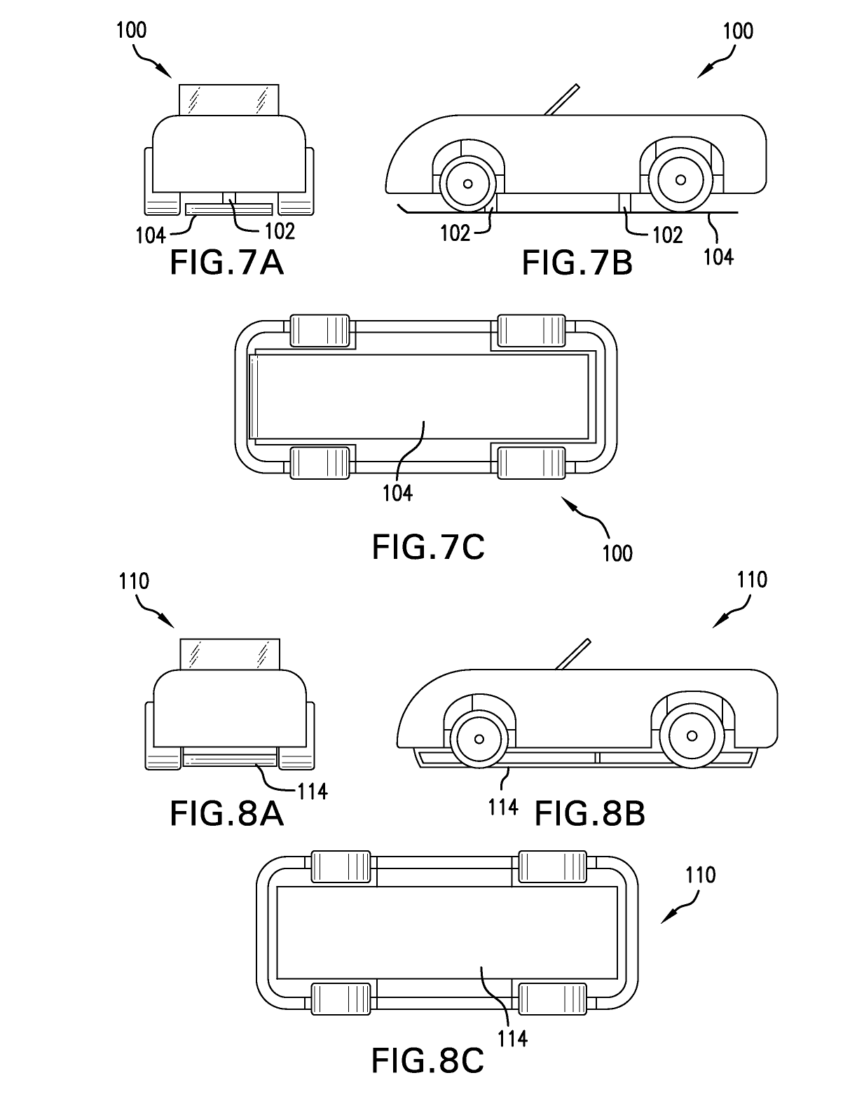

FIGS. 7A-C illustrate a play object 100 with a floating skid 104. One or two vertical sliding pins 102 couple the play object 100 to the floating skid 104 to allow the skid 104 to float and remain substantially flat against the surface of a game board or play set floor. Depending on the detection and/or identification system and method employed (discussed below), the floating skid 104 may comprise metal and/or may comprise non-conductive material. Similarly, FIGS. 8A-C illustrate a play object 110 with a fixed skid 114. The fixed skid 114 may be molded or cast as part of the play object 110 or may be mounted separately. Typically, the fixed skid 114 rides approximately 0.005″ to 0.010″ from the surface of a game board or play set while the play object 110 is positioned thereon.

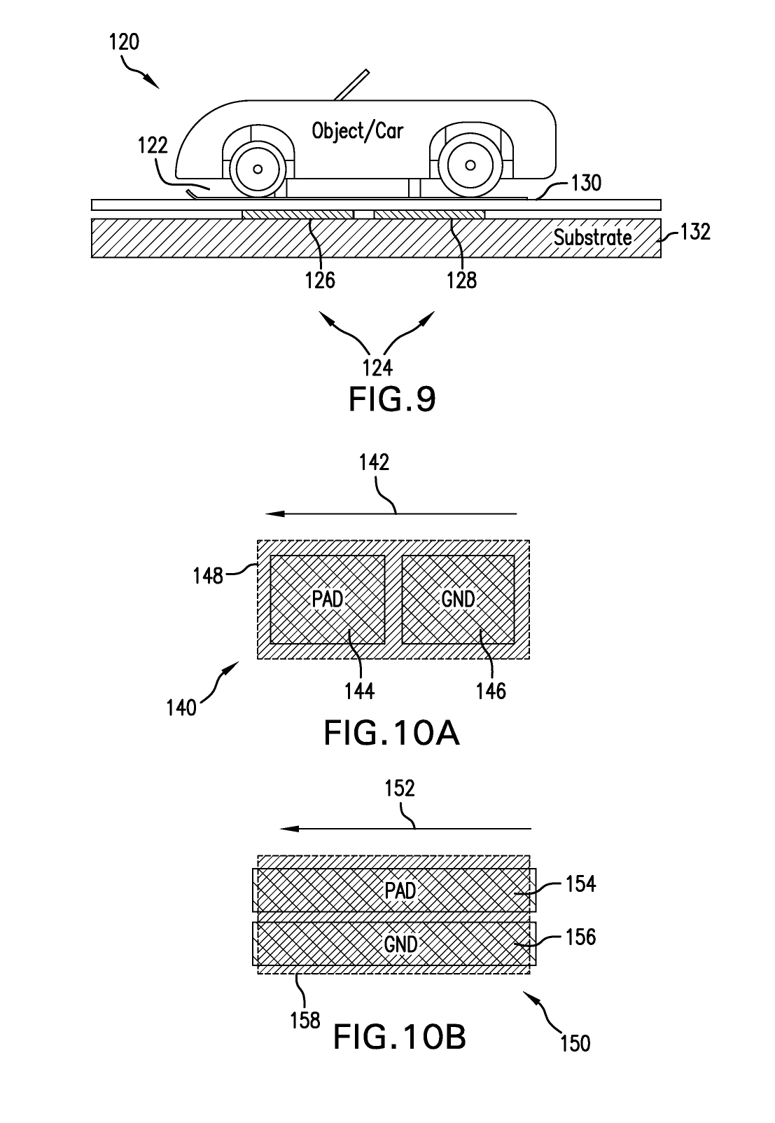

FIG. 9 illustrates a play object 120 with a skid 122 positioned over a detection sensor 124. The detection sensor 124 includes a sensor pad 126 and a ground pad 128 and is deposed on a substrate 132. A laminated non-conductive material 130 covers the detection sensor 124. The skid 122 comprises sufficient conductive material to capacitively couple the sensor pad 126 and ground pad 128 when the play object 120 is positioned over the detection sensor.

FIGS. 10A and 10B illustrates sensor pad configurations for detection sensors. The detection sensors may have two basic configurations. Like the embodiment shown in FIG. 9, in FIG. 10A, a detection sensor 140 has one pad is placed in front of the other with regards to an expected forward orientation 142 of a toy vehicle. Here, a sensor pad 144 is shown in front of a ground pad 146, but the order may be reversed. A toy vehicle skid 148 will capacitively couple the sensor pad 144 and the ground pad 146 when the toy vehicle skid 148 is positioned over the detection sensor 140. Multiple detection sensors 140 can be placed one after the other along a road printed on a game board or play set to enable detection of the toy vehicle at various points along the road. This configuration may be useful simply because most toy vehicles are longer than wide. FIG. 10B shows an alternative configuration. A detection sensor 150 has the pads parallel with regards to an expected forward orientation 152 of a toy vehicle. Here, the sensor pad 154 is shown a positioned to the right of the ground pad 156 regards to the expected forward orientation 152, but the positions could be reversed. In this embodiment as well, multiple detection sensors 150 can be placed one after the other along a road printed on a game board or play set to enable detection of the toy vehicle at various points along the road. This configuration may be useful for designs for which the vehicle's path is substantially constrained for proper alignment.

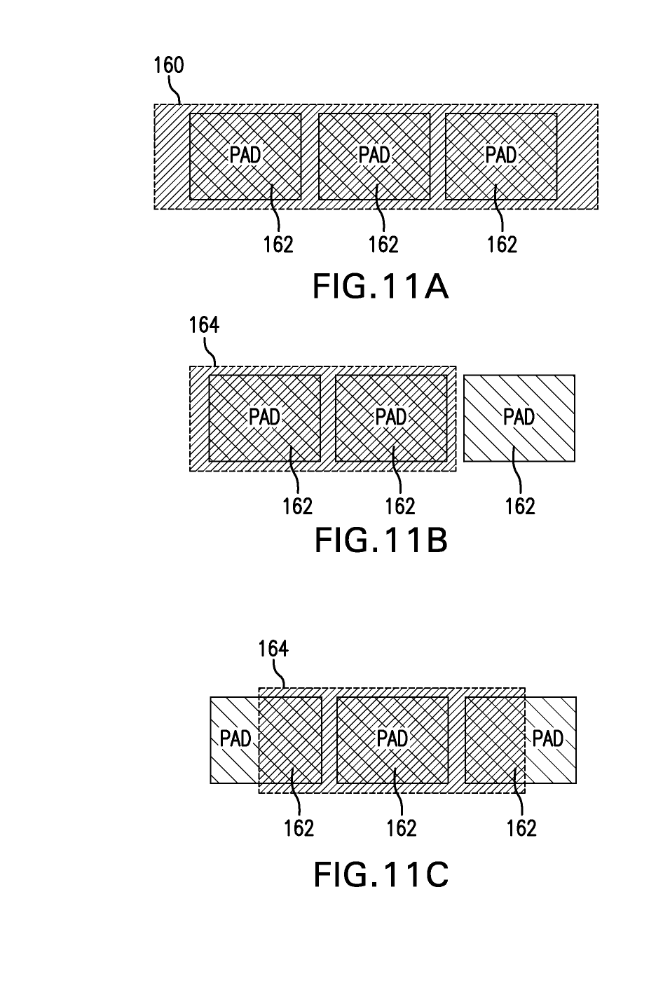

Interactive game boards or play sets may employ identification sensors to identify a variety of objects positioned on the interactive game board or play set. One method of identifying objects is to use detection sensors as shown in FIGS. 9 and 10A and have conductive skids of different lengths on the objects. Alternatively, the skids on the objects may be non-conductive and of similar lengths, but each have a conductive tab of different length on its skid. As shown in FIG. 11A a long conductive tab 160 may cover three sensor/ground pads 162. As shown in FIG. 11B, a shorter conductive tab 164 may only cover two of the pads 162 and have less capacitance than with the long conductive tab 164. Accordingly, three sensor pads may identify two different vehicles. If a shorter conductive tab 164 is misaligned as shown in FIG. 11C, it should be short enough to create a noticeably smaller signal on the two outer pads 162 since those pads will not be completely covered by the shorter conductive tab 164. Reading a sensor pad 16 array of this type may include pulling two of the three pads low (e.g., to ground) while measuring the capacitance of the third pad. This process may be done three times (once for each pad). A minimal encoding for this method is that the tab must cover at least two sensor pads.

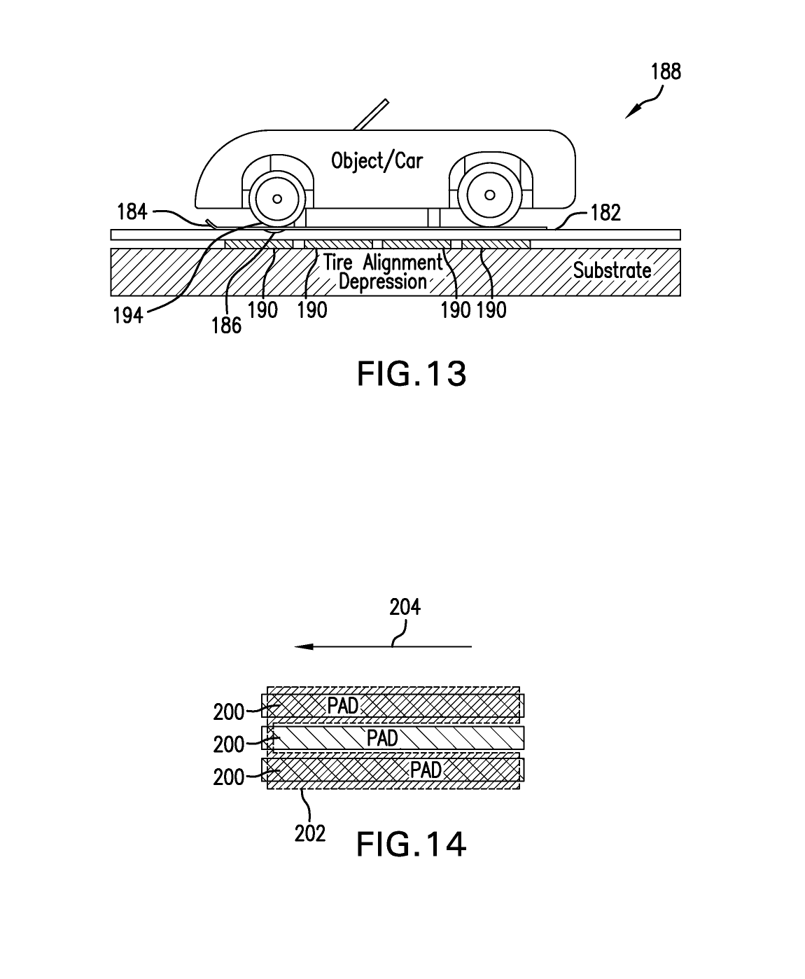

An alternative method of identifying objects on a game board or play set is to use multiple connected tabs such as in the sensor system 80 introduced in FIGS. 13 and 14. Compared to the identification embodiment illustrated by FIGS. 11A-11C, multiple connected tabs may yield more encoding options, provided the vehicle is properly aligned. This sensor system 80 comprises the switching sensor array 82 and connected tab array 83. The switching sensor array 82 has sensor pads 88 only and no ground pads. The connected tab array 83 has multiple tab locations 84 that are connected with a conductor 86 and as such may be used for more intricate encoding patterns. Reading an array of conductive pads for this type of encoding may involve pulling all pads except one low (to ground) while measuring the capacitance of the one remaining pad not pulled to ground. The process may be repeated to read the capacitance of each pad in the array. Any pad covered by a tab will have a substantially higher capacitance because it is coupled to one or more grounded pads.

In particular for vehicles, this type of encoding may support the same vehicle identification for a forward or backward orientation of the vehicle. Accordingly, the possible unique encoding for the four tab locations 84 illustrated by FIG. 13, with a 1 represented by a conductive tab 90 and a 0 indicating no conductive tab 90, may be:

1, 2, 3, 4 [1, 1, 1, 1]

1, 4 [1, 0, 0, 1]

1, 3 [1, 0, 1, 0]

1, 2 [1, 1, 0, 0]

1, 2, 4 [1, 1, 0, 1]

Alternately, an object that would not have the backward/forward orientation issue may be encoded for twice as many unique identifiers.

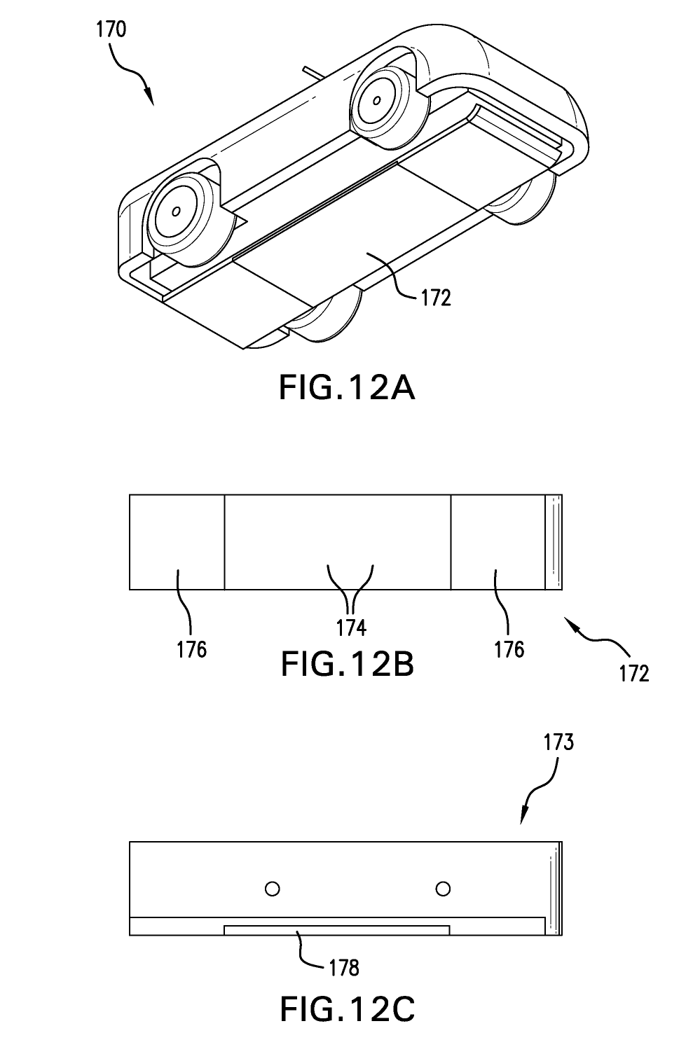

FIGS. 12A-12C illustrate one way to mount multiple connected tabs on the skid of a play object. FIG. 12A shows a play object 170 that has a non-conductive skid with a skid underside 172 and topside 173 (not shown). Conductive film may be laminated to the non-conductive skid. Alternatively, the conductive film may be screen printed on the non-conductive skid with conductive ink or the conductive film may be a laminated conductive foil that may be adhered or otherwise attached to the non-conductive skid 172. FIG. 12B shows the skid underside 172 with conductive tabs 174 adhered or otherwise attached and empty tab locations 176. FIG. 12C shows skid topside 173 with a thin conductive connecting line 178. The conductive tabs 174 wrap around to the skid top-side 173 and contact the conductive connecting line 178. In this manner, the conductive connecting line 178 may have little or no effect on “empty” pads 176 during the capacitive measurement process.

FIG. 13 illustrates an alignment system for a play object to enable correct identification. In some embodiments the configuration of sensor pads and conductive tabs may be sensitive to the alignment of the sensor pads and conductive pads to properly detect and identify the play object (e.g., toy vehicle) adjacent the sensor pads. For example, the multiple connected tabs configuration/method illustrated by FIGS. 12A-12C may be more sensitive to tab/pad alignment than simple skid length encoding. To help with this alignment, FIG. 13 illustrates three alignment aids that may be used individually and/or in combination. A play set surface 182 may include a skid alignment bump 184 (like a speed bump or a single dome) to serve as a tactile stopping place for the play object skid 192. Alternately or additionally, the play set surface 182 may include one or more small tire alignment bumps 194 (like a speed bump or a single dome) to serve as a tactile stopping place for a play object's tires. Further, the play set surface 182 may alternately or additionally include one or more tire alignment depressions 186 (e.g., like a small pothole) to serve as a tactile stopping place for the play object's tires.

FIG. 14 illustrates multiple connected tabs of an alternate embodiment to identify a toy vehicle. An alternate encoding orientation includes sensor pads 200 each running parallel in the expected forward orientation 204 of a play object 202 and corresponding conductive tabs that run the length of the play object 202. This orientation may not be as sensitive to the longitudinal orientation of the play object (i.e., the expected forward orientation 204 of the play object 202) to align the conductive tabs and pads along the length of the vehicle, but will require good lateral alignment (e.g., relative to the width of the vehicle and the driving path and/or road). Further, though described relative to multiple connected tabs, the longitudinal orientation of the sensor pads and one or more conductive tabs may also apply to length encoding as illustrated by FIGS. 11A-11B. For this embodiment, the identification of the vehicle may be determined by the width of the conductive tab instead of its length.

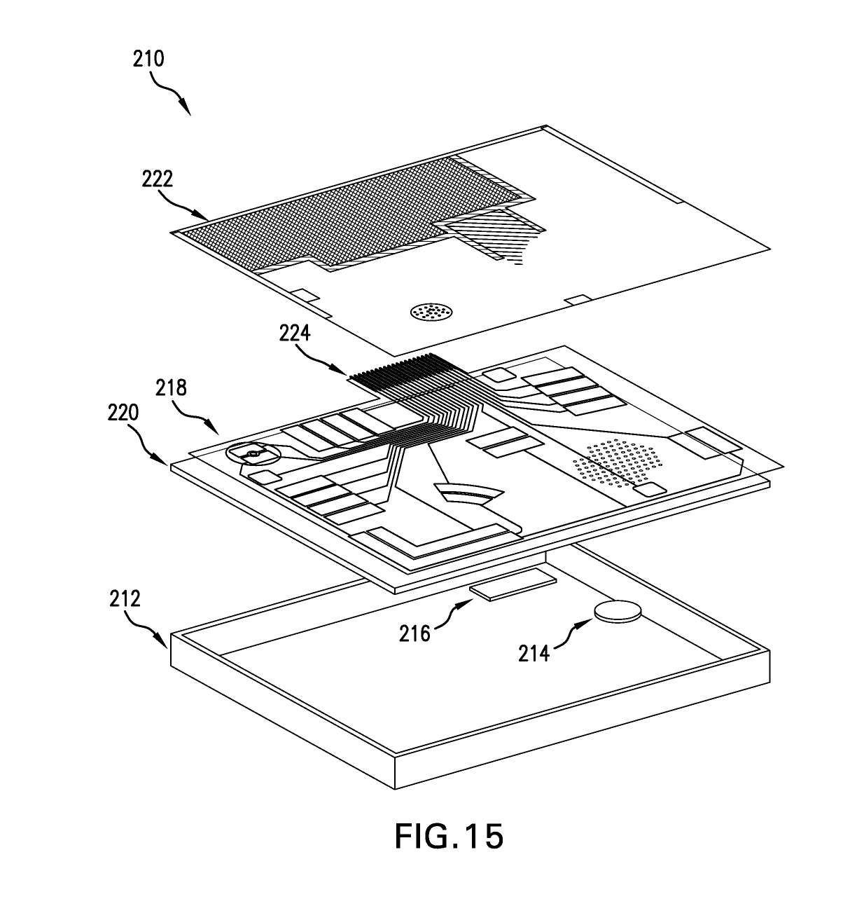

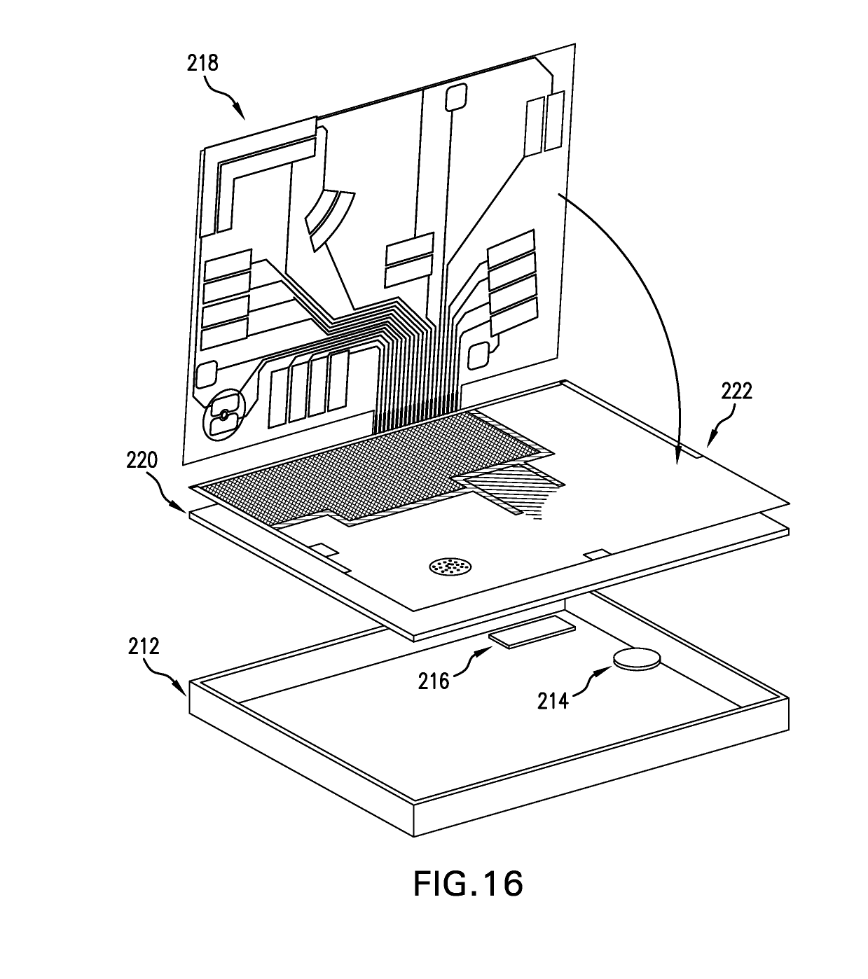

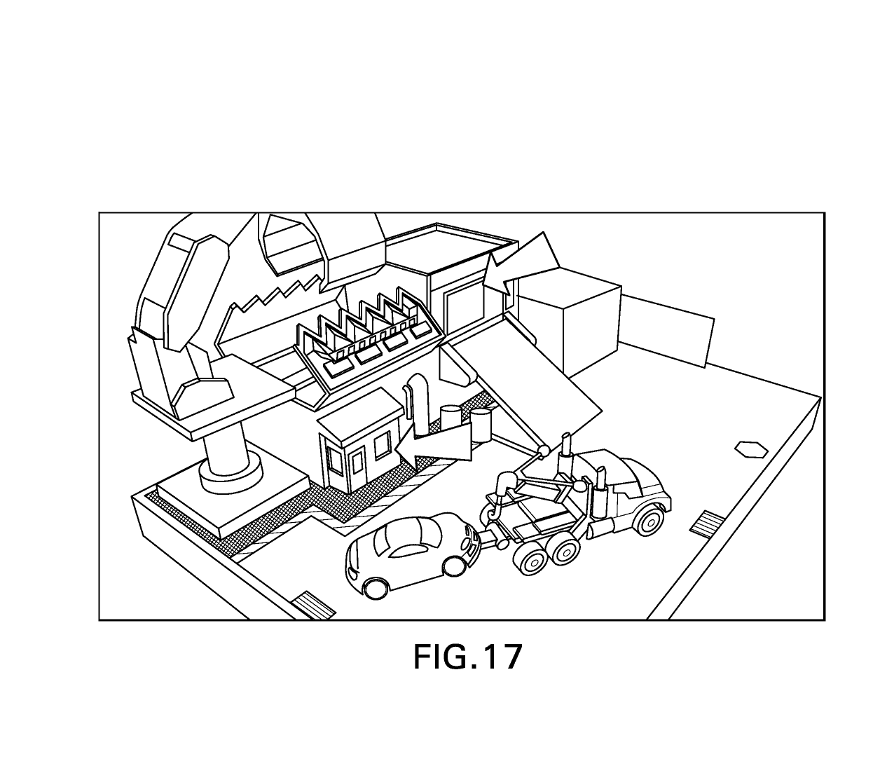

FIGS. 15-17 illustrate embodiments of play set construction. FIG. 15 for example illustrates play set 210 with a low profile enclosure 212 that houses a speaker 214 and electronic circuit pack 216. A capacitive sensor layer 218 with a capacitive sensor design deposed in conductive ink onto a thin sheet of plastic material is laminated to a top 220 of the low profile plastic enclosure 212. The capacitive sensor layer 218 has a connection bus 224 that connects with the electronic circuit pack 216 and speaker 214. A printed art layer 222 is laminated over the capacitive sensor layer 218. To finish the play set 210, buildings and other three-dimensional (3D) fixtures may be applied to the printed art layer to create a real 3D play set. FIG. 16 illustrates an alternate construction method to FIG. 15 where the color printed art layer 222 and the capacitive sensor layer 218 may be applied to a single sheet of plastic or paper. Specifically, the conductive ink forming the conductive capacitive sensors may be printed on the back of the printed art layer 222. For each embodiment, the low profile enclosure 212 may provide a substantial air gap to shield the backside of the capacitive sensors from conductive objects inadvertently altering the capacitance of the sensors. FIG. 17 shows the play set of FIG. 15 or FIG. 16 including 3D fixtures such as buildings, a ramp, and a crane.

### Play Set and Sensor Layout

The following section includes numerous play set, play set element, and sensor layout examples. The numerous examples are provided to illustrate possible combinations and designs according to various embodiments and are not meant to be exhaustive and/or restrictive.

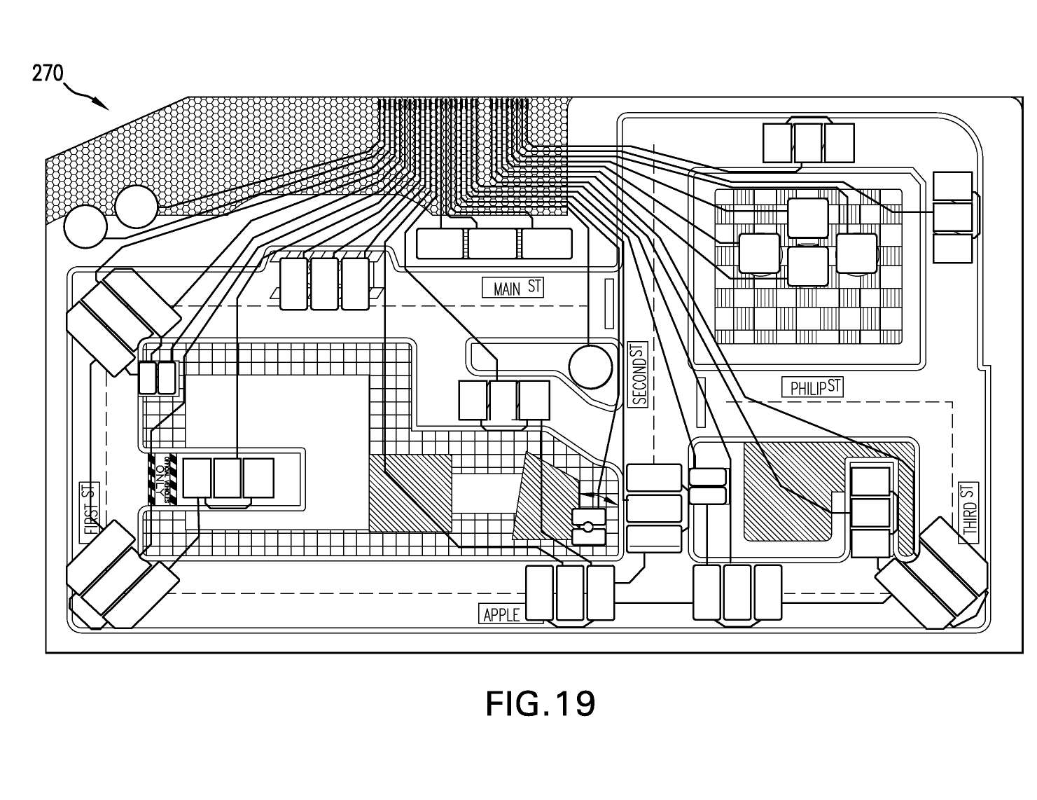

FIGS. 18 and 19 illustrate the set construction of an embodiment of play set including various elements. More specifically, FIGS. 18 and 19 illustrate a play set design 250 for a simple city layout with a bank 252, a donut shop 254, a gas station 256, a police station 258, and a fire station 260. There is also a traffic light 262 on the corner of Apple Street 264 and Second Avenue 266. FIG. 19 illustrates a capacitive sensor layout 270 for the play set of FIG. 18. In general, the play set may include one or more different types of sensors to detect, measure, identify, trigger, etc., various objects, actions, events, and the like. FIG. 19, for example, illustrates a variety of sensors for a variety of purposes. More specifically, detection sensors, touch sensors, identification sensors, and/or alternate object sensors may correspond to a variety of activates related to the city block play set. For example, one or more touch sensors may relate to filling donut orders, filling a vehicle with gasoline, starting or ending a police car activity, and/or starting or ending a fire truck activity. Further, one or more detection only sensors in the roadways may detect a vehicle going around a corner, a vehicle at an intersection with a stop light, a vehicle parking at the fire station, police station, or gas station, and/or a vehicle in the drive thru donut shop. Further, the play set may also include one identification parking spot 272 in front of the bank. The embodiments are not limited in this context.

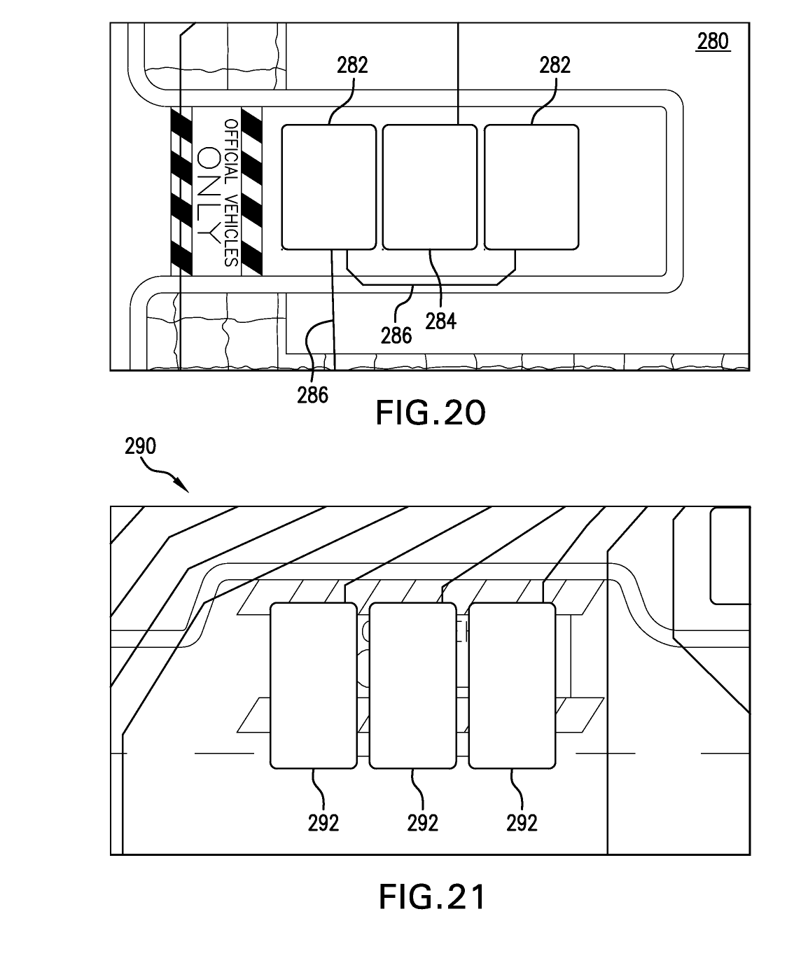

FIG. 20 illustrates a capacitive sensor for a parking space. FIG. 20 illustrates a detection parking sensor 280 that uses two ground pads 282 surrounding one sensor pad 284. In particular, the ground pads may be connected with a single trace 286. This is an effective design as it provides substantially good coupling to ground for detection. Other parking areas may alternately employ a single ground and a single sensor pad.

FIG. 21 illustrates vehicle identification sensor 290 in a parking area. Unlike the detection parking sensor illustrated by FIG. 20, the vehicle identification sensor 290 includes three sensors pads 292 but no ground pads. As also illustrated by FIGS. 13 and 14, the vehicle identification sensor 290 corresponds to a toy vehicle having multiple connected conductive tabs to encode the vehicle's identification. While it may be possible to mix in fixed ground pads into the design of FIG. 21, the inclusion of a ground pad may decrease the number of unique vehicle identifiers and/or take up more space on the play set.

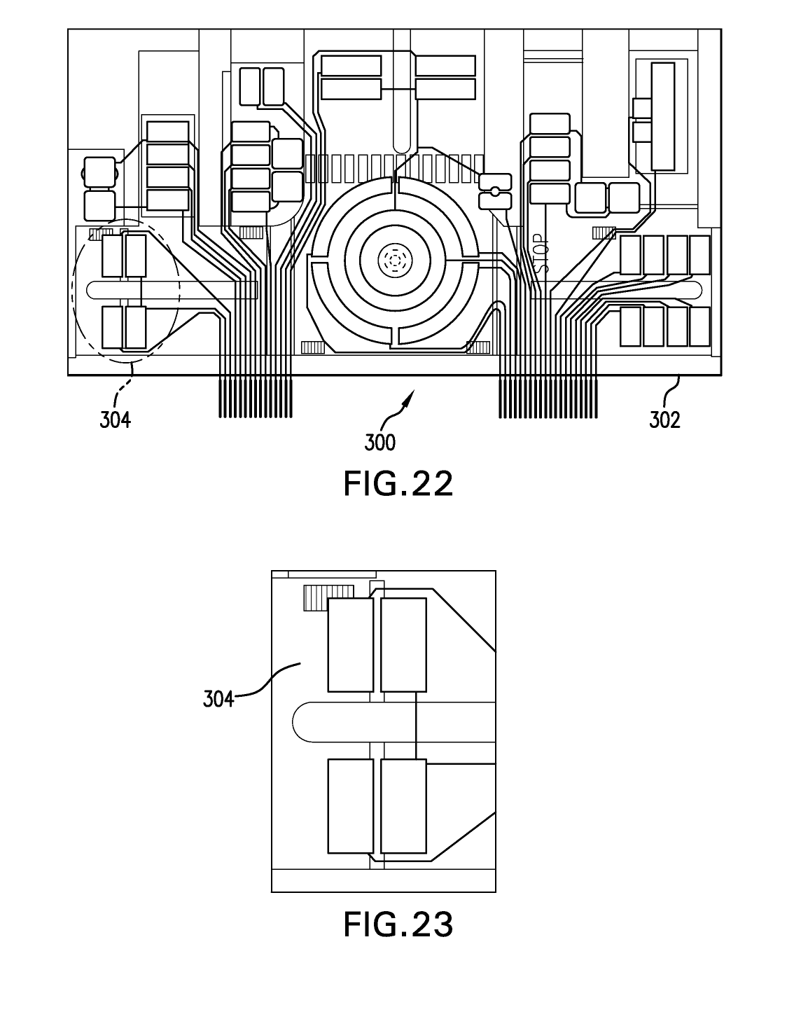

Roads printed on the play set may be natural design areas for detection sensors. As a play set user moves vehicle around the roads, detecting if the vehicle is turning a corner, driving through a stop sign or stop light, or what direction or speed the vehicle is moving may be used to create fun play interactions. For example, FIG. 22 illustrates a drag racing/drift racing play set 300. The start sensor arrays 302 in the street to the right (e.g., at the start line, and including four pads each) may be used to identify vehicles preparing to race. The racing play set 300 may be configured to play recordings of engines revving and trash talk. When the race starts, these same staring sensor arrays 302 can be used to know when each car starts racing. If a car leaves too soon, the racing place set can announce that it is disqualified. As each vehicle leaves, the starting sensor arrays 302 can trigger the play of, for example, engine rev and tire squeal sounds. Alternately, FIG. 23 illustrates finish sensor arrays 304 at the finish line of a race. The finish sensor arrays may be single point detection sensors to tell when a vehicle has finished a race and which one wins. Identification is not used here as the vehicles will still be moving when they finish.

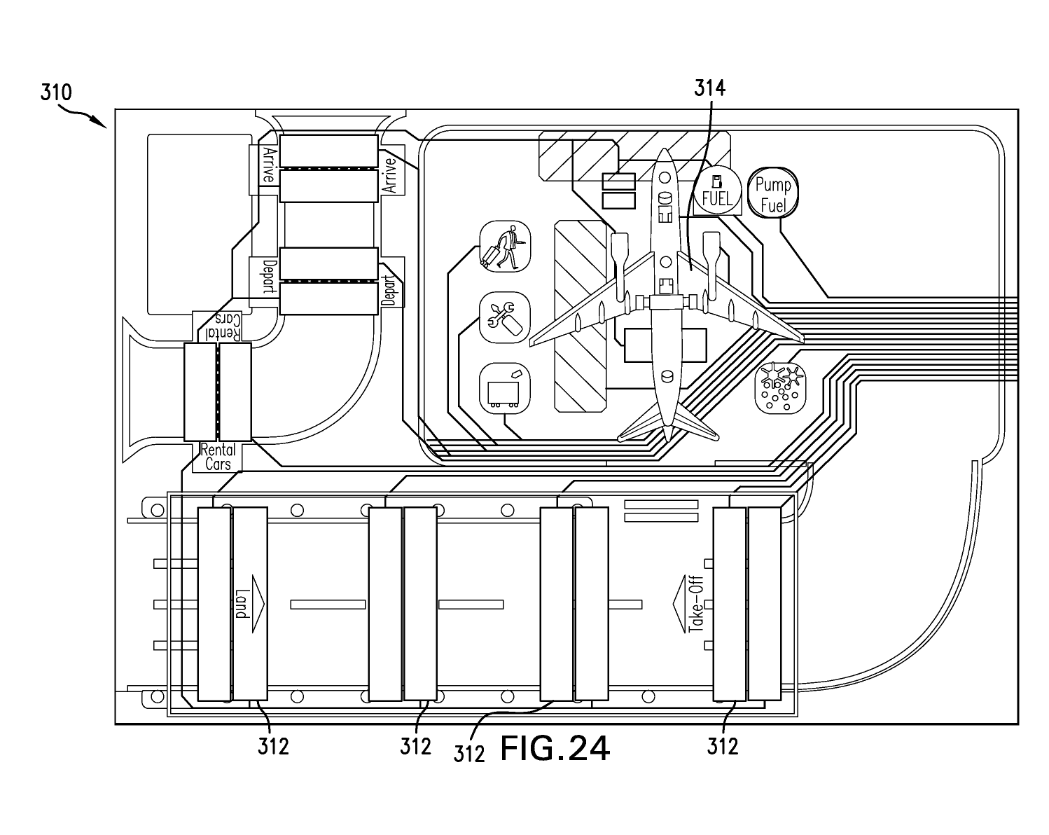

FIG. 24 illustrates an airport play set 310 including multiple runway sensors 312. Multi-point detection on a street or other surface where a vehicle moves may be typically used to know speed and direction. For example, the airplane runway for the airport play set 310 in FIG. 24 employs a set of four detection sensors 312. If a plane play object 314 is detected moving from left to right it has just landed and landing sounds are played. If the plane play object 314 is moving right to left on the runway, it is taking off and take-off sounds are played. If the plane is moving too slowly on the runway for take-off the pilot may be warned.

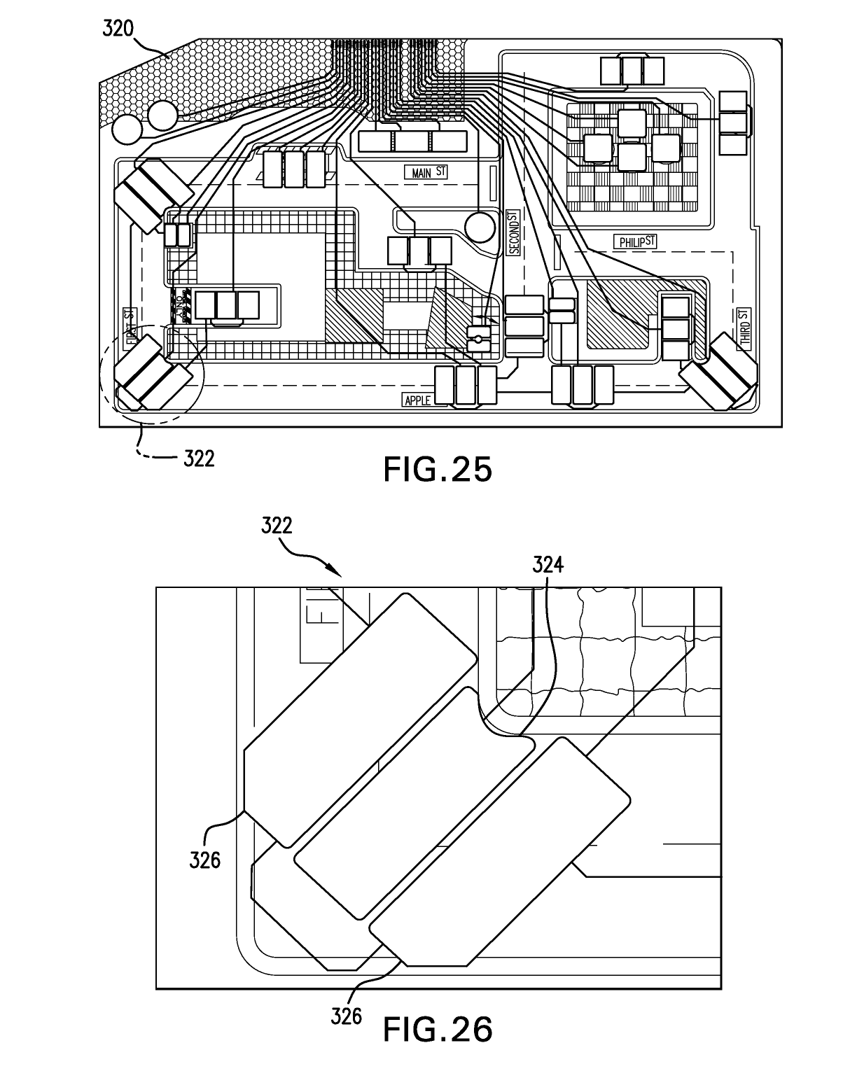

FIG. 25 illustrates a street block play set 320. One interactive feature may be to use street corner detection sensors 322. When a vehicle goes around a corner, the play set may play tire screeching audio sounds. FIG. 26 illustrates the street corner detection sensors 322. The street corner detection sensors 322 may include a single sensor pad 324 positioned and/or sandwiched between two ground pads 326 that are interconnected.

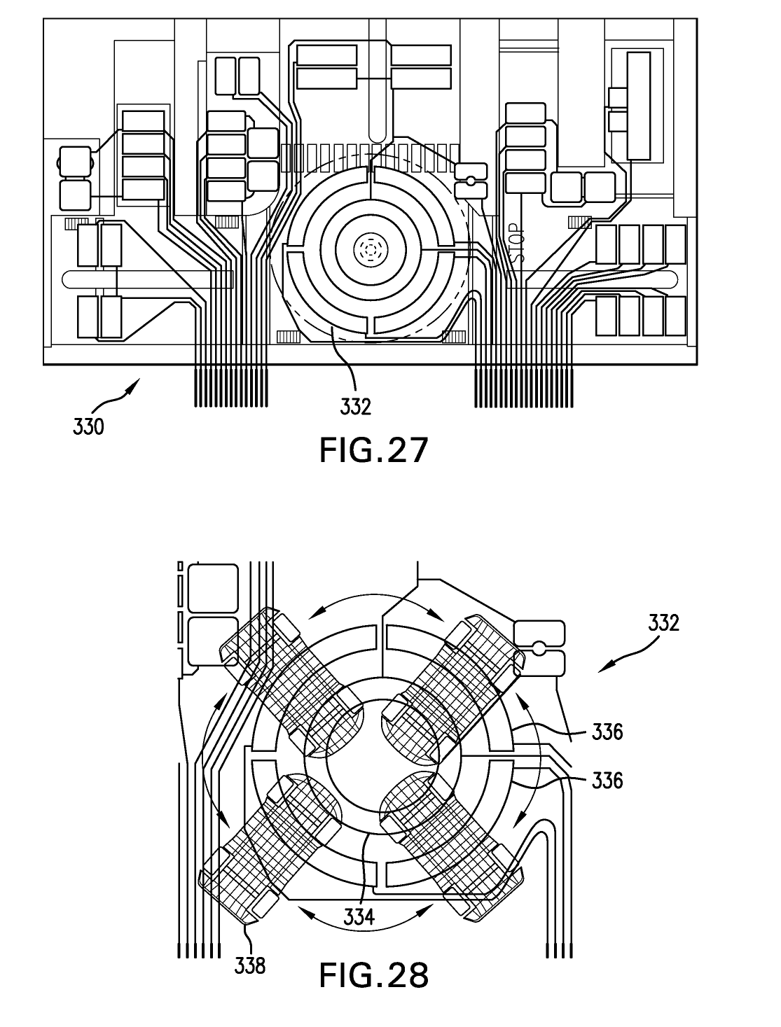

Another embodiment including vehicle cornering may be a drift racing play set. For example, FIG. 27 illustrates a drift racing play set 330 including a large two-ring sensor 332 substantially in the center of the play set. More specifically, FIG. 28 illustrates use of the two-ring sensor 332. The inside ring 334 of the two-ring sensor 332 may be a ground pad. The four outside ring segments 336 may be sensor pads. When a toy vehicle 334 is turned sideways and moves around this area in a circle, the vehicle skid plate may overlap both the ground and sensor pad 16s. Each pad segment allows the drift racing play set 330 to know that the car is moving in a circle and the speed of that movement so that the drift racing play set 330 can play appropriate sound effects.

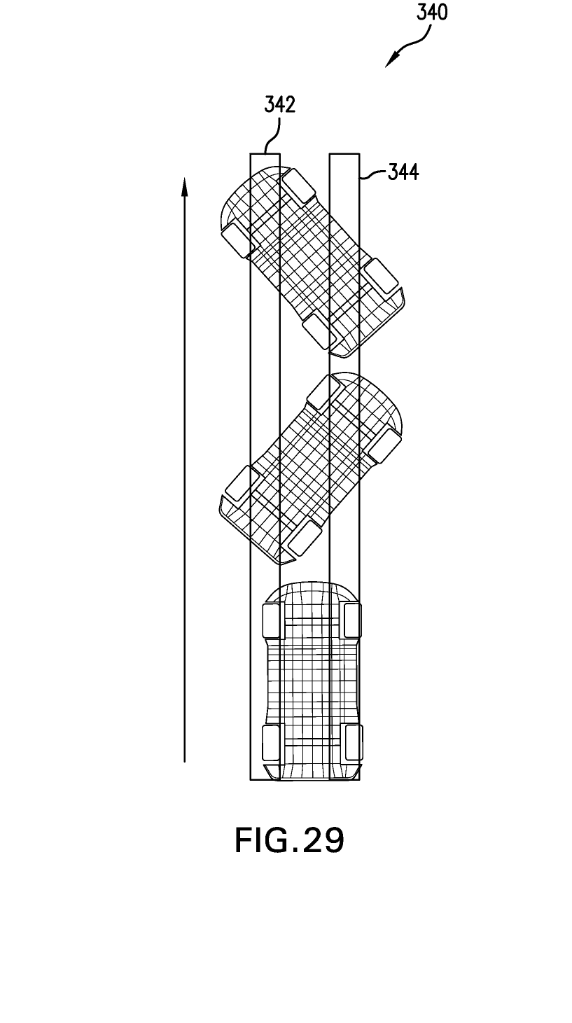

More generally, FIG. 29 illustrates a skidding sensor 340 configured to detect a vehicle skidding motion. The play set may include two strips, one a ground pad 342 and the other a sensor pad 344 along a roadway printed on a play set, with the strips separated far enough so that a vehicle traveling down the roadway will not be detected (though other sensor pads may be used to detect linear movement of the vehicle along the roadway). When the vehicle is twisted or rotated, its skid plate may couple to both the sensor pad 344 and ground pad 342. The play set may accordingly detect the skidding motion and may play skidding noises.

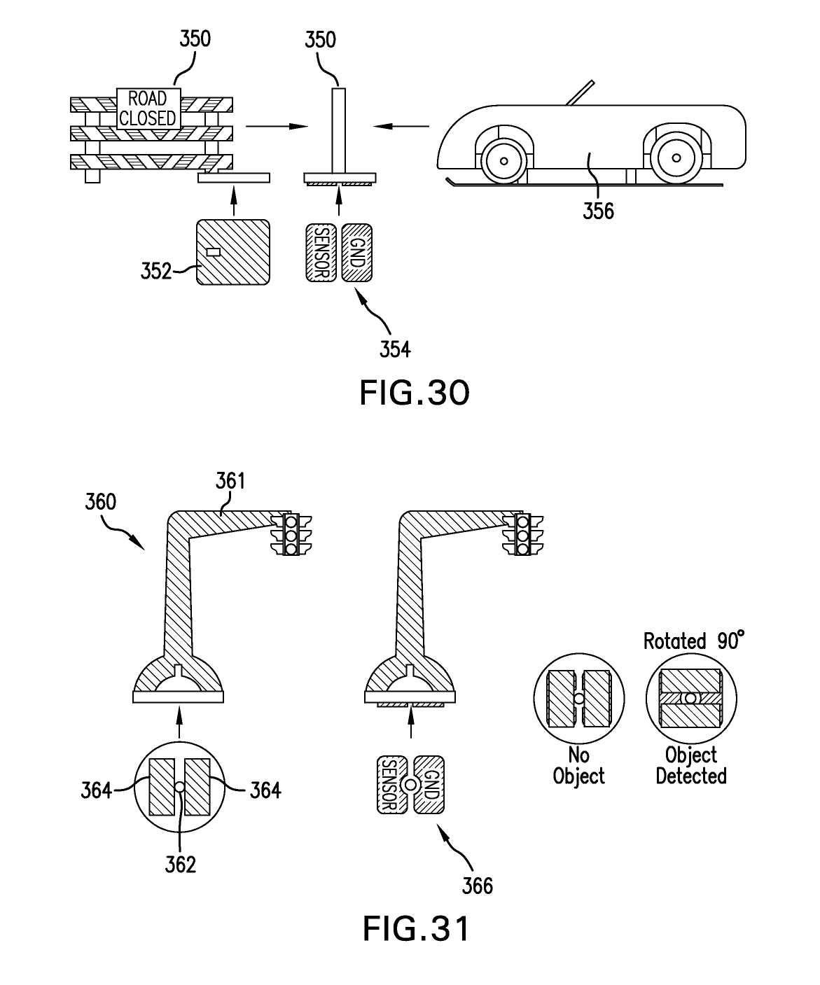

FIG. 30 illustrates road barriers in a play set. A road barrier 350 is a play object that has a single conductive tab 352 for detection. The play set may include designated locations for road barriers 350 that include small sensor/ground pad pairs 354. When a vehicle 356 runs through or otherwise moves the road barrier 352, the corresponding small sensor/ground pad 354 pair will no longer detect the road barrier 352. The play set may accordingly play a crashing sound in response.

FIG. 31 illustrates a traffic light in a play set. More specifically, a traffic light may be used at a road intersection to stop vehicle traffic on one of the two streets at the intersection. For example, a traffic light 360 with a traffic light arm 361 may be mounted on a center-pin 362 that allows the traffic light 360 to pivot 90 degrees. Two rectangular conductive tabs 364 on the base the traffic light 360 may be the same size and shape as a pair of sensor/ground pads 366 underneath the traffic light 360 on the play set. When the traffic light 360 is at one 90 degree position, the conductive tabs 364 will not be detected, thus the play set knows the rotational position of the traffic light 360. At the other 90 degree position, the conductive tabs 364 will be detected and the set knows the new position of the traffic light 360. By detecting the position of the traffic light 360, the play set may determine which one or more streets have a red light and which one or more streets have a green light.

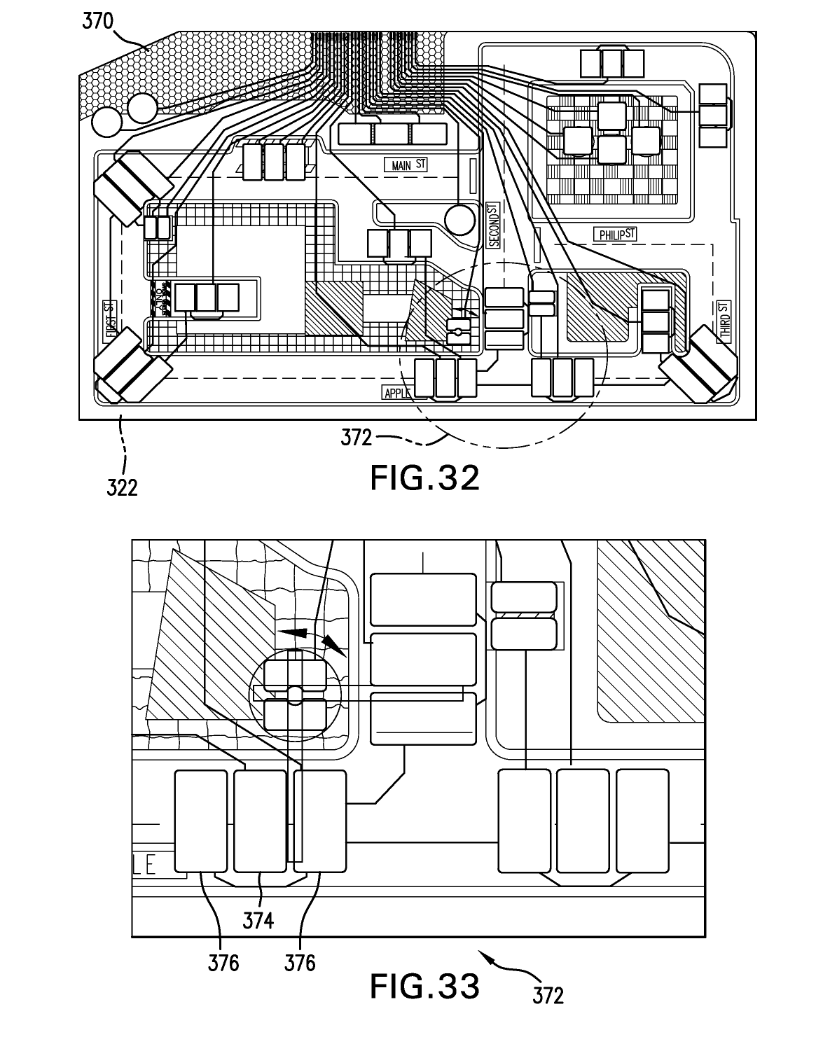

FIG. 32 illustrates a street block play set 370 including intersection capacitive sensors 372. More specifically, FIG. 33 illustrates intersection capacitive sensors 372 in combination with the traffic light 360 illustrated by FIG. 31. When the traffic light arm 361 is positioned over the vertical street, this indicates a red light. When the traffic light arm 361 is rotated 90 degrees so that it is over the horizontal street has a red light. The intersection capacitive sensors 372 are detection capacitive sensors having a sensor pad 374 positioned/sandwiched between two ground pads 376 that are electrically coupled together. Accordingly, if the intersection capacitive sensors 372 detect the departure of a vehicle while they have a red light, the play set may play a vehicle horn sound, a vehicle crash sound, or the like to indicate that a vehicle has run a red light.

Those skilled in the art will recognize that numerous modifications and changes may be made to the preferred embodiment without departing from the scope of the claimed invention. It will, of course, be understood that modifications of the invention, in its various aspects, will be apparent to those skilled in the art, some being apparent only after study, others being matters of routine mechanical, chemical and electronic design. No single feature, function or property of the preferred embodiment is essential. Other embodiments are possible, their specific designs depending upon the particular application. As such, the scope of the invention should not be limited by the particular embodiments herein described but should be defined only by the appended claims and equivalents thereof.

I claim:

1. A capacitive sensing play set comprising:
a substrate;
a capacitive sensor layer adjacent the substrates;
a dielectric layer adjacent the capacitive sensor layer; and
a play object including one or more conductive tabs.

2. The capacitive sensing play set of claim 1, the capacitive sensor layer further comprising one or more capacitive touch sensors, one or more capacitive detection sensors, one or more capacitive identification sensors, or a combination thereof.

3. The capacitive sensing play set of claim 2, the one or more capacitive detection sensors, one or more capacitive identification sensors, or a combination thereof further comprising one or more sensor pads to detect the one or more conductive tabs.

4. The capacitive sensing play set of claim 2, the one or more capacitive detection sensors, one or more capacitive identification sensors, or a combination thereof further comprising one or more sensor pads and one or more ground pads adjacent the one or more sensor pads, the one or more sensor pads to detect the one or more conductive tabs.

5. The capacitive sensing play set of claim 2, the one or more capacitive touch sensors further comprising one or more substantially one-sided capacitive touch sensors shielded by a conductive ground plane layer.

6. The capacitive sensing play set of claim 2, the one or more capacitive touch sensors further comprising one or more substantially one-sided capacitive touch sensors shielded by an air gap layer.

7. The capacitive sensing play set of claim 1, the dielectric layer further comprising an insulator layer at least approximately 0.5 mm thick.

8. The capacitive sensing play set of claim 7, the dielectric layer further comprising a printed art layer opposite the capacitive sensor layer.

9. The capacitive sensing play set of claim 2, the play object further comprising a toy vehicle including a skid.

10. The capacitive sensing play set of claim 9, the skid further including the one or more conductive tabs.

11. The capacitive sensing play set of claim 10, the one or more conductive tabs further comprising one or more connected conductive tabs.

12. The capacitive sensing play set of claim 11, the one or more connected conductive tabs to encode an identity of the toy vehicle.

13. The capacitive sensing play set of claim 11, the one or more connected conductive tabs to uniquely identify the vehicle to the one or more capacitive identification sensors.

14. A capacitive sensing play set comprising:
an enclosure including an air gap;
a substrate adjacent the enclosure;
a capacitive sensor layer adjacent the substrate; and
a dielectric layer adjacent the capacitive sensor layer.

15. The capacitive sensing play set of claim 14, the capacitive sensor layer further comprising one or more capacitive touch sensors, one or more capacitive detection sensors, one or more capacitive identification sensors, or a combination thereof.

16. The capacitive sensing play set of claim 15, the one or more capacitive detection sensors, one or more capacitive identification sensors, or a combination thereof further comprising one or more sensor pads.

17. The capacitive sensing play set of claim 15, the one or more capacitive detection sensors, one or more capacitive identification sensors, or a combination thereof further comprising one or more sensor pads and one or more ground pads adjacent the one or more sensor pads.

18. The capacitive sensing play set of claim 14 wherein the play object further comprises a toy vehicle including a skid.

19. The capacitive sensing play set of claim 18, the skid further comprising one or more conductive tabs.

20. The capacitive sensing play set of claim 19, the one or more conductive tabs to identify the play object.

21. The capacitive sensing play set of claim 14, the enclosure further comprising a control circuit.

22. An interactive play set comprising:
one or more play objects, each including one or more conductive tabs; and
a game board including one or more capacitive sensors responsive to the one or more conductive tabs to detect the play object.

23. The interactive play set of claim 22, the game board to detect a position of one of the play objects.

24. The interactive play set of claim 22, the game board configured to detect a motion of one of the play objects.

25. The interactive play set of claim 22, the game board configured to detect an identification of one of the play objects.

26. The interactive play set of claim 22, further comprising:
a speaker coupled to the game board;
an electronic circuit pack coupled to the game board and configured to detect changes in capacitance of the one or more capacitive sensors and further configured to play sound effects on the speaker in response to the capacitance changes detected.

27. The interactive play set of claim 22, the game board further comprising:
one or more capacitive sensors responsive to the one or more conductive tabs to identify of one of the play objects.
